(19) United States
(12) Patent Application Publication
(10) Pub. No.: US 2026/0279423 A1
(43) Pub. Date: Sep. 17, 2026

(54) MEMORY DEVICE AND OPERATING METHOD OF THE MEMORY DEVICE

(71) Applicant: Samsung Electronics Co., Ltd., Suwon-si (KR)

(72) Inventors: Daeshik Kim, Suwon-si (KR); Gyuseong Kang, Suwon-si (KR); Hyunjin Shin, Suwon-si (KR)

(21) Appl. No.: 19/552,269

(22) Filed: Feb. 27, 2026

(30) Foreign Application Priority Data
Mar. 11, 2025 (KR) 10-2025-0031656

(51) Int. Cl. G11C 11/16; G11C 17/18

(52) U.S. Cl. CPC G11C 11/1673; G11C 11/161; G11C 11/1655; G11C 11/1659; G11C 17/18; G11C 11/1657

(57) ABSTRACT

A memory device includes a controller configured to generate a control signal based on a type of a memory cell, to perform a read operation of the memory device, a cell array including a normal memory area including a normal memory cell capable of multiple programming, a one-time programmable (OTP) memory area including an OTP memory cell capable of one-time programming, a normal reference area including a normal reference cell corresponding to the normal memory cell, and an OTP reference area including an OTP reference cell corresponding to the OTP memory cell, and a sense amplifier configured to generate a comparison signal by detecting a difference between an input signal applied from the memory cell and a reference signal applied from the reference cell. The normal reference cell and the OTP reference cell are configured to share a target reference bit line.

### CROSS-REFERENCE TO RELATED APPLICATION

This application claims the benefit of an earlier filing date and right of priority under 35 U.S.C. §119(a) to Korean Patent Application No. 10-2025-0031656, filed on Mar. 11, 2025, in the Korean Intellectual Property Office, the disclosure of which is incorporated by reference herein in its entirety.

### BACKGROUND

A resistive memory device may store data in a memory cell that includes a variable resistance element. The variable resistance element may include a magnetic tunnel junction (MTJ) element. As an example, the MTJ element may include two magnetic bodies and an insulating film provided therebetween. The resistance value of the MTJ element may vary depending on the magnetization directions of the two magnetic bodies. For example, when the magnetization directions of two magnetic bodies are anti-parallel to each other, the MTJ element may have a large resistance value, and when the magnetization directions of two magnetic bodies are parallel to each other, the MTJ element may have a small resistance value. By using the difference between the resistance values, data may be programmed or read.

### SUMMARY

The disclosure provides a memory device, and a method of operating the memory device. In an intellectual property (IP) block (or one memory chip) that includes a normal memory cell and a one-time programmable (OTP) memory cell, by sharing a reference bit line between a normal reference cell and an OTP reference cell, an increase in the size of a core area that is otherwise needed for accommodating a separate reference bit line may be prevented, and a read margin of the normal memory cell and the OTP memory cell may be improved.

According to an aspect of the disclosure, there is provided a memory device including a controller configured to generate a control signal based on a type of a memory cell, to perform a read operation of the memory device, a cell array including a normal memory area including a normal memory cell capable of multiple programming, an OTP memory area including an OTP memory cell capable of one-time programming, a normal reference area including a normal reference cell corresponding to the normal memory cell, and an OTP reference area including an OTP reference cell corresponding to the OTP memory cell, and a sense amplifier configured to generate a comparison signal by detecting a difference between an input signal applied from the memory cell and a reference signal applied from the reference cell, wherein the normal reference cell and the OTP reference cell are configured to share a target reference bit line.

According to another aspect of the disclosure, there is provided a method of operating a memory device, the memory device including a normal memory cell capable of multiple programming, an OTP memory cell capable of one-time programming, a normal reference cell, an OTP reference cell, and a reference switching circuit, the method including based on a control signal received from a memory controller, determining whether a read operation is a read operation of the normal memory cell or a read operation of the OTP memory cell, in response to determining that the read operation is the read operation of the normal memory cell, generating a first reference resistance value based on a resistive element of the reference switching circuit, by turning off a switch transistor of the reference switching circuit, and in response to determining that the read operation is the read operation of the OTP memory cell, bypassing the resistive element of the reference switching circuit by turning on the switch transistor of reference switching circuit, and generating a second reference resistance value by combining a plurality of OTP reference cells, wherein the normal reference cell and the OTP reference cell are configured to share a target reference bit line and are connected to the reference switching circuit through the target reference bit line.

According to another aspect of the disclosure, there is provided a memory system including a memory controller, and a memory device including a cell array and a reference switching circuit, the cell array including a normal memory cell capable of multiple programming, an OTP memory cell capable of one-time programming, a normal reference cell, and an OTP reference cell, and the reference switching circuit connected to the cell array through a target reference bit line, wherein the normal reference cell and the OTP reference cell are configured to share the target reference bit line, and wherein the memory device generates a first reference signal based on a resistive element of the reference switching circuit when a read operation is a read operation of the normal memory cell, by using the target reference bit line, and generates a second reference signal based on a switch transistor of the reference switching circuit and a variable resistance element of the OTP reference cell, by using the target reference bit line, when the read operation is a read operation of the OTP memory cell.

### BRIEF DESCRIPTION OF THE DRAWINGS

Implementations will be more clearly understood from the following detailed description taken in conjunction with the accompanying drawings.

FIG. 1 is a block diagram of a memory device according to some implementations.

FIG. 2A illustrates an example of a memory cell according to some implementations.

FIG. 2B illustrates an example of a reference cell according to some implementations.

FIG. 3 is a graph showing dispersion of resistance values of a memory cell and a reference cell, according to some implementations.

FIG. 4A is a diagram illustrating a cell array according to some implementations.

FIG. 4B is a diagram illustrating a cell array according to some implementations.

FIG. 5 is a diagram illustrating a structure of a memory device in a read operation of the memory device, according to some implementations.

FIG. 6 is a diagram illustrating a wiring structure associated with a reference bit line and a reference cell of a memory device according to some implementations.

FIG. 7 is a diagram illustrating a wiring structure associated with a reference bit line and a reference cell of a memory device according to some implementations.

FIG. 8 is a diagram illustrating a wiring structure associated with a reference bit line and a reference cell of a memory device according to some implementations.

FIG. 9 is a diagram illustrating a wiring structure associated with a reference bit line and a reference cell of a memory device according to some implementations.

FIG. 10 is a flowchart of a method of operating a memory device, according to some implementations.

FIG. 11 is a block diagram of a memory system including a memory device according to some implementations.

FIG. 12 is a block diagram illustrating a system-on-chip including a memory device according to some implementations.

### DETAILED DESCRIPTION

A resistivity memory device may include a normal memory cell and a one-time programmable (OTP) memory cell. Each of the normal memory cell and the OTP memory cell may include a variable resistance element. The normal memory cell may store data or read stored data by using the variable resistance element. The OTP memory cell can be programmed only once, and once programmed, the contents cannot be changed and are retained even after power is removed.

The OPT memory cell can be used for security-critical data such as the setting value of a memory device. The OTP memory cell can store security-critical data, and when reading out data from the OTP memory cell, errors need to be minimized. Accordingly, interest in technology that combines a normal memory cell and an OTP memory cell into an intellectual property (IP) block (or a memory chip) is increasing. However, an OTP reference cell may require a separate reference bit line as the OTP reference cell generates a reference signal method different from the normal reference cell.

This disclosure provides a memory device in which a reference bit line between a normal reference cell and a one-time programmable (OTP) reference cell is shared. Such a memory device is desired, for example, when combining the normal memory cell and the OTP memory cell into an IP block.

Hereinafter, implementations of the disclosure are described below in detail with reference to the accompanying drawings. Throughout the drawings, like reference numerals are used for like elements, and redundant descriptions thereof are omitted.

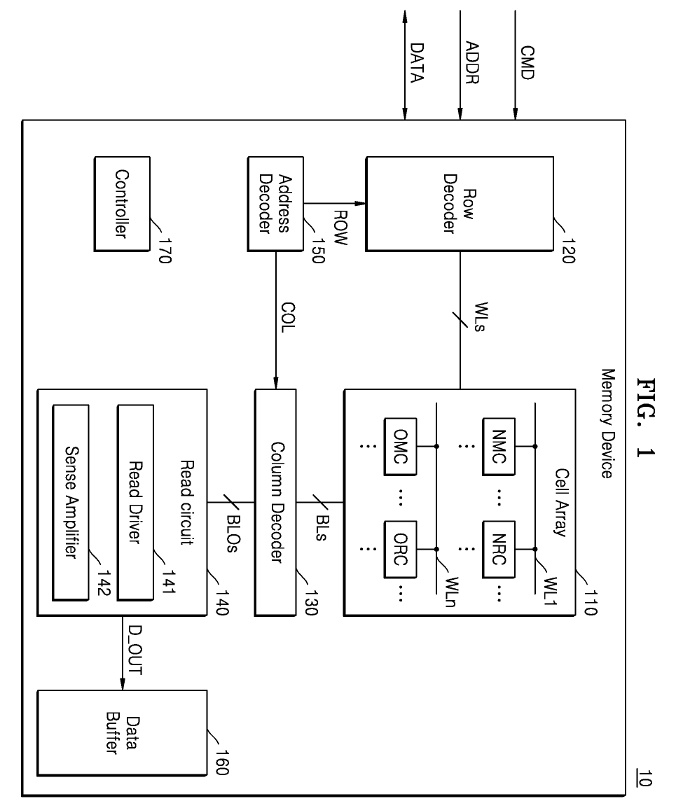

FIG. 1 is a block diagram of a memory device 10 according to some implementations.

Referring to FIG. 1, the memory device 10 may include a cell array 110, a row decoder 120, a column decoder 130, a read circuit 140, an address decoder 150, a data buffer 160, and a controller 170.

The memory device 10 may receive a command CMD and an address ADDR, and receive or output data DATA. For example, the memory device 10 may receive, from a memory controller, for example, the command CMD, such as a write command or a read command, and the address ADDR corresponding to the command CMD. Furthermore, the memory device 10 may receive the data DATA (i.e., write data) from the memory controller, or provide the data DATA (i.e., read data) to the memory controller. In some implementations, at least two or more of the command CMD, the address ADDR, and the data DATA may be received or output through the same channel.

The cell array 110 may include a plurality of memory cells, such as normal memory cells (NMCs) and one-time programmable (OTP) memory cells (OMCs). The cell array 110 may include the memory cells (NMCs and OMCs) arranged in rows and columns. The memory cells (NMCs and OMCs) may be connected to a plurality of word lines WLs. The memory cells connected to a single word line may be referred to as a page, and data may be read or written in units of pages.

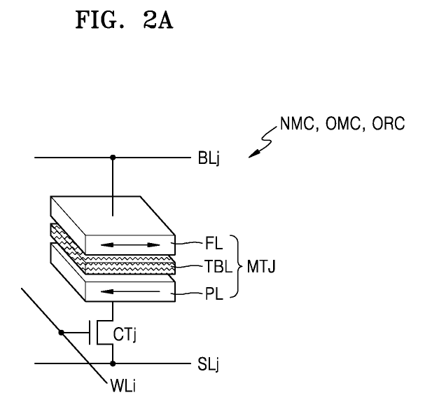

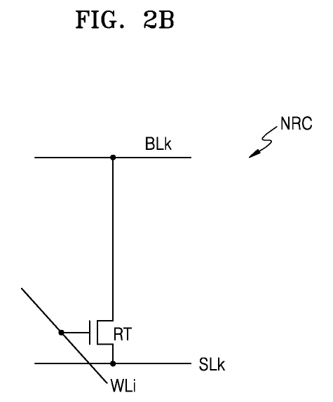

In some implementations, each memory cell may include a variable resistance element (e.g., MTJ in FIG. 2A), and the variable resistance element MTJ may have a resistance corresponding to a value (or a bit) stored in the memory cell. In the following description, the NMC and the OMC may be referred to as a memory cell, and a normal reference cell (NRC) and an OTP reference cell (ORC) may be referred to as a reference cell. When the memory cell includes the variable resistance element MTJ, the memory device 10 may be referred to as a resistive memory device. For example, the memory device 10 may include, as a non-limiting example, the cell array 110 having a magnetic random access memory (MRAM) structure, such as spin-transfer torque magnetic random access memory (STT-MRAM), spin torque transfer magnetization switching RAM (Spin-RAM), or spin momentum transfer (SMT-RAM), or the cell array 110 having a structure, such as phase change random access memory (PRAM) or ferroelectric random access memory (FRAM). In the following description, the implementations of the disclosure are described mainly with reference to MRAM, the implementations of the disclosure are not limited thereto.

In the memory device 10, each of the memory cells (NMCs and OMCs) may include a cell transistor (e.g., a cell transistor CTj in FIG. 2A) and the variable resistance element MTJ. The cell array 110 may include the word lines WLs, a plurality of bit line BLs, and a plurality of source lines (e.g., a source line SLj in FIG. 2A) which are connected to the memory cells (NMCs and OMCs). Each of the word lines WLs may be connected to a gate of a cell transistor of each of the memory cells (NMCs and OMCs) positioned in one of rows of the cell array 110, and the bit lines BLs and the source lines may be respectively connected to the variable resistance element MTJ and a source of the cell transistor of the memory cells (NMCs and OMCs) positioned in one of columns of the cell array 110.

The cell array 110 may include the NMC and the OMC. The NMC may refer to a memory cell that generally operates to store data and is programmable multiple times. The OMC may refer to a memory cell that operates for an OTP function. The OMC is capable of one-time programming. In some implementations, the NMC and the OMC may be implemented as one memory chip, and the memory device 10 may simultaneously use the NMC and the OMC through one memory chip.

The cell array 110 may include the NMC and the OMC which are connected to different word lines WLs. For example, the NMCs may be connected to a word line WL1, and the OMCs may be connected to a word line WLn. The cell array 110 of FIG. 1 illustrates one row including the NMC and one row including the OMC, but the disclosure is not limited thereto, and the cell array 110 may include at least one row including the NMC and at least one row including the OMC. Furthermore, FIG. 1 illustrates that the NMC and the OMC are connected to different word lines WLs and share the bit line BL, but the disclosure is not limited thereto, and the NMC and the OMC may be configured to share the same word line WL.

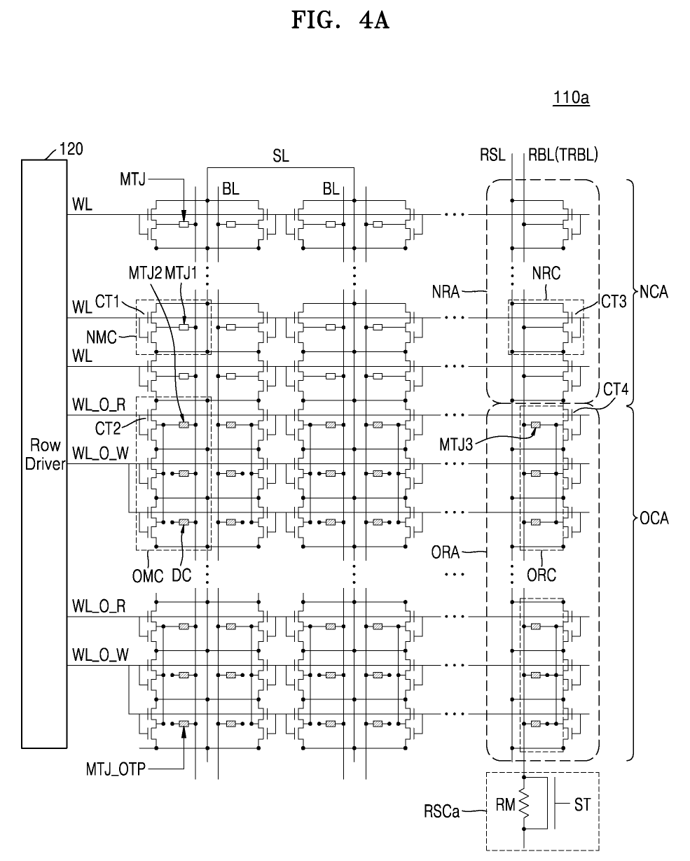

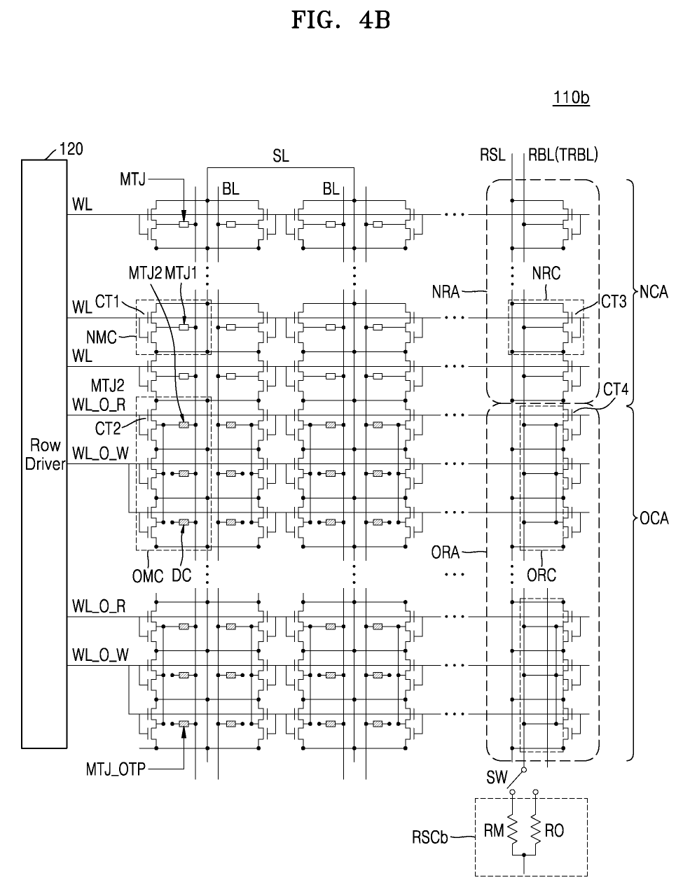

The NMC and the OMC may each include a variable resistance element and a cell transistor. In the following description, the variable resistance element and the cell transistor included in the NMC are referred to as a first variable resistance element (e.g., a first variable resistance element MTJ1 in FIG. 4A) and a first cell transistor (e.g., a first cell transistor CT1 in FIG. 4A), respectively, and the variable resistance element and the cell transistor included in the OMC are referred to as a second variable resistance element (e.g., a second variable resistance element MTJ2 in FIG. 4A) and a second cell transistor (e.g., a second cell transistor CT2 in FIG. 4A), respectively. The row of the NMCs may be connected to the word line WL1 corresponding thereto, and the row of the OMCs may be connected to the word line WLn corresponding thereto.

The OMC is capable of one-time programming, and once programmed, contents may not be changed and are retained even after power is removed. The OMC may store security-critical data. For example, the OMC can store digital security tokens, smart cards, keys, passwords, boot codes, producing settings, manufacturing settings, setting values of the memory device 10, trim values, etc. The second variable resistance element MTJ2 of the OMC may have an irreversible resistance state (i.e., a breakdown state) by applying a breakdown voltage BV to the OMC through a one-time programming operation to destruct the insulation of a tunnel barrier layer (e.g., a barrier layer TBL in FIG. 2A).

As the OMC stores security-critical data such as the setting value of the memory device 10, the OMC needs to be implemented as one chip with the NMC as an essential element of the memory device 10. As described below with reference to the drawings, the memory device 10 may prevent occurrence of word line offset due to use of separate reference bit lines by sharing a reference bit line between the NRC and the ORC (i.e., the NRC and the ORC are connected to the same reference bit line), thereby improving the read margin of the memory device 10. Accordingly, occurrence of errors may be reduced when reading data stored in the NMC and the OMC, and data reliability may be improved. Furthermore, as the cell array 110 and peripheral circuits may be used without change, the memory device 10 may have a simple structure and a low cost. Furthermore, as separate reference bit lines, the cell array 110, and peripheral circuits for storing security-critical data may be omitted, a system including the memory device 10 may have a simple structure and a low cost.

In some implementations, the structure of the OMC may be the same as the structure of the NMC. For example, the NMC may include one first cell transistor and one first variable resistance element. The OMC may include one second cell transistor and one second variable resistance element. However, the disclosure is not limited thereto. The structure of the OMC may be different from the structure of the NMC. For example, the NMC may include one first cell transistor and one first variable resistance element. The OMC may include three second cell transistors and one second variable resistance element or six second cell transistors and one second variable resistance element.

The cell array 110 may include a plurality of reference cells (NRCs and ORCs). The cell array 110 may include the NRCs and the ORCs. The NRC may refer to a reference cell corresponding to the NMC. The NRC may be connected to the word line WL corresponding to the NMC. As an example, the NMC and the NRC may share the word line WL1. The NRC may be used to determine a value stored in the NMC. When one of the word lines WLs is activated by the row decoder 120 and the activated word line WL corresponds to the NMC, not only the NMC connected to the activated word line WL1, but also the NRC connected to the activated word line WL1 may be selected. For example, the NMC and the NRC may be selected by the activated word line WL1.

When the value stored in the NMC is determined, the NRC corresponding to the NMC may be used. As an example, the NRC selected by the same word line as the NMC may be used to read the data stored in the NMC. The NRC may have a first reference resistance value. In some implementations, the NRC may include a resistive element such as a variable resistance element, and that the NRC has the first reference resistance value may mean that the resistance value of the resistive element included in the NRC corresponds to the first reference resistance value. However, the disclosure is not limited thereto, and in some implementations, the NRC may be a shorted cell in which a resistive element such as a variable resistance element is omitted. When the NRC is a shorted cell, the target reference bit line TRBL may include a resistance circuit (e.g., a resistive element RM of a reference switching circuit RSC in FIG. 4A) connected to the NRC outside the cell array 110. That the NRC has the first reference resistance value may mean that a resistance value of the resistance circuit (e.g., the resistive element RM of the reference switching circuit RSC in FIG. 4A) connected to the NRC corresponds to the first reference resistance value.

The data stored in the NMC may be read based on the first reference resistance value. As an example, in order to determine the data stored in the NMC, the resistance value of the first variable resistance element MTJ1 of the NMC may be compared with the first reference resistance value of the NRC.

The ORC may refer to a reference cell corresponding to the OMC. The ORC may be connected to a word line WLn corresponding to the OMC. As an example, the OMC and the ORC may share the word line WLn. The ORC may be used to determine a value stored in the OMC. When one of the word lines WLs is activated by the row decoder 120 and the activated word line WL corresponds to the OMC, not only the OMC connected to the activated word line WL, but also the ORC connected to the activated word line WL may be selected. For example, the OMC and the ORC may be selected by the activated word line WLn.

When the value stored in the OMC is determined, the ORC corresponding to the OMC may be used. As an example, the ORC selected by the same word line as the OMC may be used to read the data stored in the OMC. The ORC may have a second reference resistance value. In some implementations, the ORC may include a resistive element such as a variable resistance element, and that the ORC has the second reference resistance value may mean that a resistance value of the resistive element included in the ORC corresponds to the second reference resistance value. The second reference resistance value of the ORC may be generated based on connection/combination between a plurality of ORCs (e.g., the variable resistance elements of the ORCs). However, the disclosure is not limited thereto, and in some implementations, the ORC may be a shorted cell in which a resistive element such as a variable resistance element is omitted.

The data stored in the OMC may be read based on the second reference resistance value. As an example, in order to determine the data stored in the OMC, the resistance value of the second variable resistance element MTJ2 of the OMC may be compared with the second reference resistance value of the ORC.

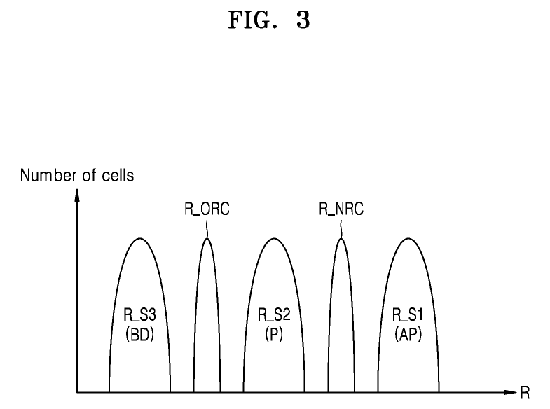

In some implementations, the first reference resistance value of the NRC may be different from the second reference resistance value of the ORC. The first reference resistance value may be a resistance value to distinguish a parallel state (e.g., a parallel state R_S2 (P) in FIG. 3) of the NMC from an anti-parallel state (e.g., an anti-parallel state R_S1 (AP) in FIG. 3) of the NMC. The second reference resistance value may be a resistance value to distinguish a breakdown state (e.g., a breakdown state R_S3 (BD) in FIG. 3) of the OMC from a non-breakdown state (e.g., the non-breakdown state that is not a breakdown state may include the parallel state R_S2 (P) and the anti-parallel state R_S1 (AP) in FIG. 3). In other words, the first reference resistance value may be a resistance value to distinguish the parallel state P from the anti-parallel state AP of the variable resistance element of the memory cell, and the second reference resistance value may be a resistance value to distinguish the breakdown state BD from the non-breakdown state of the variable resistance element. As an example, the first reference resistance value may be an intermediate value between the resistance value of the parallel state P and the resistance value of the anti-parallel state AP of the variable resistance element, and the second reference resistance value may be an intermediate value between the resistance value of the breakdown state BD and the resistance value of the parallel state P of the variable resistance element. However, the disclosure is not limited thereto.

The row decoder 120 may activate at least one of the word lines WLs based on a row address ROW provided by the address decoder 150, and the memory cells and the reference cells connected to the activated word line may be selected. For example, the row decoder 120 may, in response to the row address ROW, activate one of the word lines WLs connected to the NMC, or activate one of the word lines WLs connected to the OMC.

The column decoder 130 may be connected to the cell array 110 through the bit lines BLs. The column decoder 130 may select the memory cell based on a column address COL provided by the address decoder 150. In some implementations, the column decoder 130 may select the memory cell based on the column address COL, and select a reference cell corresponding to the selected memory cell. For example, the column decoder 130 may, based on the column address COL, select the NMC, and select the NRC corresponding to the NMC. The column decoder 130 may, based on the column address COL, select the OMC, and select the ORC corresponding to the OMC.

The read circuit 140 may be connected to the column decoder 130 through output bit lines BLOs. As an example, the output bit lines BLOs may include a first output bit line and a second output bit line, and the read circuit 140 may determine a value stored in the memory cell based on signals received through the first output bit line and the second output bit line, and generate a data signal D_OUT including the determined value. For example, the first output bit line may be connected to the memory cell, and the second output bit line may be connected to the reference cell, but the disclosure is not limited thereto.

The read circuit 140 may provide a preset electrical signal to each of the memory cell and the reference cell, and detect signals passing through the memory cell and the reference cell, thereby determining the value stored in the memory cell. In the read operation of the NMC, the read circuit 140 may provide a preset electrical signal to each of the NMC and the NRC, and determine the value stored in the NMC by detecting, through the output bit lines BLOs, the signals passing through the NMC and the NRC. In the read operation of the NMC, the read circuit 140 may read the data stored in the NMC based on the first reference resistance value. The read circuit 140 may determine the value stored in the NMC by using a signal generated based on the first reference resistance value, through the output bit lines BLOs connected to the NRC and the NRC.

In the read operation of the OMC, the read circuit 140 may provide a preset electrical signal to each of the OMC and the ORC, and determine the value stored in the OMC by detecting the signals passing through the OMC and the ORC, through the output bit lines BLOs. In the read operation of the OMC, the read circuit 140 may read the data stored in the OMC based on the second reference resistance value. The read circuit 140 may determine the value stored in the OMC by using the signal generated based on the second reference resistance value, through the ORC and the output bit lines BLOs connected to the ORC.

In some implementations, in the read operation of the OMC, the read circuit 140 may write the OMC in an anti-parallel state and then read the data stored in the OMC based on the second reference resistance value. As an example, the second reference resistance value may be a resistance value to distinguish the breakdown state from the anti-parallel state of the OMC. In the read operation of the OMC, there is a need to distinguish the breakdown state from the non-breakdown state, and the non-breakdown state may include the parallel state and the anti-parallel state. The resistance value corresponding to the breakdown state may be less than the resistance value of the parallel state, and the resistance value of the parallel state may be less than the anti-resistance value of the parallel state.

The read circuit 140 may include a read driver 141 and a sense amplifier 142. However, although not illustrated in FIG. 1, the read circuit 140 may further include, as necessary, other components than the read driver 141 and the sense amplifier 142. The read circuit 140 may provide an electrical signal of a preset amplitude to the memory cell and the reference cell, and determine the value stored in the memory cell by detecting currents passing through the memory cell and the reference cell. In detail, the read driver 141 may provide an electrical signal of a preset amplitude to the memory cell and the reference cell. The sense amplifier 142 may detect the currents passing through the memory cell and the reference cell.

In some implementations, the read circuit 140 may provide a current of a preset amount to each of the memory cell and the reference cell. The electrical signal may include a current, and the read driver 141 may provide a current of a preset amount to the memory cell and the reference cell. In some implementations, the read driver 141 may include a current generator that provides a current to the memory cell and the reference cell. The sense amplifier 142 may be a voltage sense amplifier. The sense amplifier 142 may determine the value stored in the memory cell by detecting voltages applied to the memory cell and the reference cell.

In some implementations, the read circuit 140 may provide a voltage of a preset amount to each of the memory cell and the reference cell. The electrical signal may include a voltage, and the read driver 141 may provide a voltage of a preset amount to the memory cell and the reference cell. In some implementations, the read driver 141 may include a voltage generator that provides a voltage to the memory cell and the reference cell. The sense amplifier 142 may be a current sense amplifier. The sense amplifier 142 may determine the value stored in the memory cell by detecting the currents passing through the memory cell and the reference cell. Although not illustrated in FIG. 1, the memory device 10 may further include a write circuit to write data to the memory cells.

Although not illustrated in FIG. 1, the memory device 10 may include the reference switching circuit RSC connected to the NRC and the ORC through a target reference bit line. The reference switching circuit RSC may include a resistive element and a switch transistor. The reference switching circuit RSC may turn a select transistor on or off according to a control signal of the controller 170. For example, for the read operation of the NMC, the reference switching circuit RSC may turn the select transistor off according to a first control signal of the controller 170, and the first reference signal may be generated based on the resistive element of the reference switching circuit RSC. For the read operation of the ORC, the reference switching circuit RSC may turn the select transistor on according to a second control signal of the controller 170 (i.e., by bypassing the resistive element of the reference switching circuit RSC), and the first reference signal may be generated based on the variable resistance element of the ORC.

In the read operation of the NMC, the sense amplifier 142 may determine the value stored in the NMC by detecting a difference between the first read voltage value applied from the NMC and the first reference signal applied from the NRC based on a first electrical signal. In the read operation of the OMC, the sense amplifier 142 may determine the value stored in the OMC by detecting a difference between the second read voltage value applied from the OMC and a second reference signal applied from the ORC based on a second electrical signal.

The address decoder 150 may generate the row address ROW and the column address COL based on the address ADDR. The data buffer 160 may receive the data signal D_OUT from the read circuit 140, and store data corresponding to the data signal D_OUT. The data buffer 160 may provide the stored data to an input/output circuit.

Although not illustrated in FIG. 1, the memory device 10 may further include the input/output circuit. The input/output circuit may provide a memory interface. For example, the input/output circuit may externally receive the command CMD and the address ADDR, and externally receive the data DATA or output the data DATA to the outside. The input/output circuit may provide the address ADDR to the address decoder 150, and provide the command CMD and the address ADDR to the controller 170. The input/output circuit may provide the received data DATA to the data buffer 160, and output the data signal D_OUT provided from the data buffer 160, as the data DATA, to the outside.

The controller 170 may control the overall operation of the memory device 10. The controller 170 may control the components of the memory device 10 based on the command CMD. For example, the controller 170 may identify instructions for a write operation or a read operation based on the command CMD, and control the components to perform the write operation or the read operation.

In some implementations, the controller 170 may control the components based on the address ADDR. As the NMC and the OMC may be connected to different word lines, the read operation of the NMC and the read operation of the OMC may be distinguished from each other based on the address ADDR. As an example, the controller 170 may distinguish the read operation of the OMC from the read operation of the NMC based on the row address ROW and a command, and control the components to perform the read operation of the OMC. However, the disclosure is not limited thereto, and the read operation of the OMC may be distinguished from the read operation of the NMC based on the column address COL.

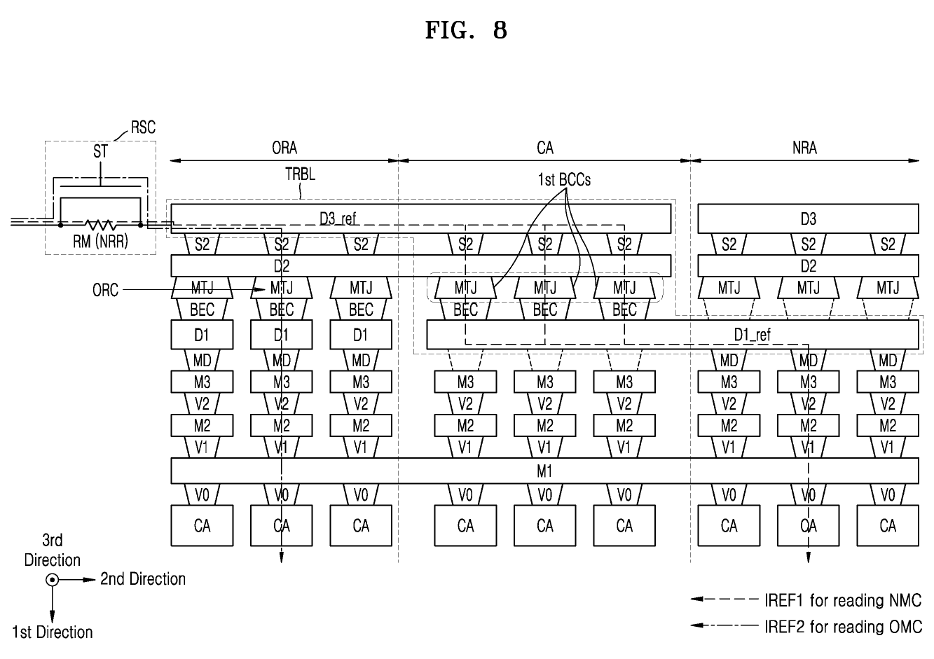

In order to prevent I/O offset, the controller 170 may preset all of the first bit line connection cells (1st BCCs in FIG. 8) to be in a parallel state or an anti-parallel state, before the read operation.

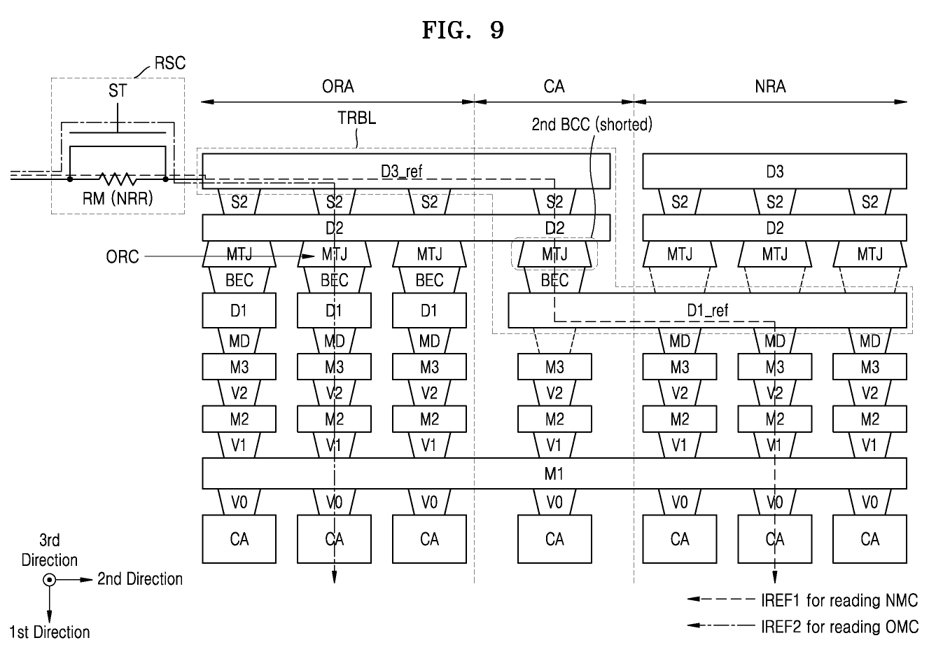

The controller 170 may preset, to prevent word line offset, a second bit line connection cell (a 2nd BCC in FIG. 9) to be in a breakdown state by applying a high bias of a preset amount to the second bit line connection cell, before the read operation.

In the memory device 10 according to the disclosure and the method of operating the memory device 10, in an intellectual property (IP) block that includes the NMC and the OMC, by sharing a reference bit line between the NRC and the ORC, an increase in the size of a core (or a memory chip) area that is otherwise needed for accommodating a separate reference bit lines may be prevented, and deterioration of the word line WL offset properties may be prevented, thereby improving the read margin of the memory cell.

Furthermore, in the memory device 10 according to the disclosure and the method of operating the memory device 10, by sharing a reference bit line between the NRC and the ORC, the read margin of each memory cell may be increased based on low IC design complexity.

FIG. 2A illustrates an example of the memory cell according to some implementations. The structures of the NMC, the OMC, and the ORC in FIG. 2A may be applied to the NMC, the OMC, and the ORC in FIG. 1, respectively. Content overlapping with the above-described content is omitted.

Referring to FIG. 2A, the NMC, the OMC, and the ORC may each include the variable resistance element MTJ and the cell transistor CTj which are serially connected between a bit line BLj and the source line SLj. However, the disclosure is not limited thereto, and the NMC, the OMC, and the ORC according to some implementations may omit the variable resistance element MTJ. In the case of the NMC, the variable resistance element MTJ may be a first variable resistance element, and the cell transistor CTj may be a first cell transistor. In the case of the OMC, the variable resistance element MTJ may be a second variable resistance element, and the cell transistor CTj may be a second cell transistor. In the case of the ORC, the variable resistance element MTJ may be a third variable resistance element, and the cell transistor CTj may be a third cell transistor. Although FIG. 2A illustrates that the NMC, the OMC, and the ORC may each include one variable resistance element MTJ and one cell transistor CTj, which is merely an example, and the numbers of the variable resistance elements and the cell transistors included in each of the NMC, the OMC, and the ORC may vary.

In some implementations, as illustrated in FIG. 2A, the variable resistance element MTJ and the cell transistor CTj may be connected in such an order between the bit line BLj and the source line SLj, and in some implementations different from the illustration in FIG. 2A, the cell transistor CTj and the variable resistance element MTJ may be connected in such an order between the bit line BLj and the source line SLj.

The variable resistance element MTJ may include a free layer FL, a pinned layer PL, and the barrier layer TBL between the free layer FL and the pinned layer PL. As indicated by arrows in FIG. 2A, while the magnetization direction of the pinned layer PL may be fixed, the free layer FL may have a magnetization direction that is the same as or opposite to the magnetization direction of the pinned layer PL. When the pinned layer PL and the free layer FL have the same magnetization direction, the variable resistance element MTJ may be referred to as being in a parallel state (e.g., the parallel state R_S2 (P) in FIG. 3), and when the pinned layer PL and the free layer FL have the opposite magnetization directions, the variable resistance element MTJ may be referred to as being in an anti-parallel state (e.g., the anti-parallel state R_S1 (AP) in FIG. 3). In some implementations, the variable resistance element MTJ may further include an anti-ferromagnetic layer so that the pinned layer PL has a fixed magnetization direction. Although FIG. 2A illustrates, for convenience of explanation, that the magnetization directions of the free layer FL and the pinned layer PL are horizontal directions, the disclosure is not limited thereto, and in the variable resistance element MTJ according to some implementations, the magnetization directions of the free layer FL and the pinned layer PL may be vertical directions.

In the case of the NMC, the variable resistance element MTJ may have a relatively low resistance value (e.g., R_S2 in FIG. 3) in the parallel state P, and a relatively high resistance value (e.g., R_S1 in FIG. 3) in the anti-parallel state AP. In the specification, in the case of the NMC, it is assumed that when the variable resistance element MTJ in the parallel state P has a low resistance value R_S2, a memory cell stores "0", and when the variable resistance element MTJ in the anti-parallel state AP has a high resistance value R_S1, the memory cell stores "1".

The cell transistor CTj may include a gate connected to a word line WLi, and a source and a drain respectively connected to the source line SLj and the variable resistance element MTJ. The cell transistor CTj may electrically connect or disconnect the variable resistance element MTJ and the source line SLj according to a signal applied to the word line WLi. For example, in the write operation, in order to write "0" to the NMC, the cell transistor CTj may be turned on, a current flowing from the bit line BLj to the source line SLj may pass through the variable resistance element MTJ and the cell transistor CTj. Furthermore, in order to write "1" to the NMC, the cell transistor CTj may be turned on, and a current flowing from the source line SLj to the bit line BLj may pass through the cell transistor CTj and the variable resistance element MTJ. In the read operation, the cell transistor CTj may be turned on, and the current flowing from the bit line BLj to the source line SLj, or the current flowing from the source line SLj to the bit line BLj, that is, a read current, may pass through the cell transistor CT and the variable resistance element MTJ.

In the case of the OMC, the variable resistance element MTJ may have a relatively low resistance value (e.g., R_S2 in FIG. 3) in the parallel state P, and a relatively high resistance value (e.g., R_S1 in FIG. 3) in the anti-parallel state AP, whereas may have a relatively further low resistance value (e.g., R_S3 IN FIG. 3) in a breakdown state (e.g., the breakdown state BD in FIG. 3). The cell transistor CTj may apply, to the OMC, a breakdown current that is higher than a typical write current applied to the variable resistance element MTJ. The breakdown current may damage or destroy the barrier layer TBL of the variable resistance element MTJ. The further low resistance value R_S3 in the breakdown state BD is lower than the low resistance value R_S2 in the parallel state P and the high resistance value R_S1 in the anti-parallel state AP. When the variable resistance element MTJ is in the breakdown state BD, the variable resistance element MTJ may not be changed to another state.

In the following description, in the OMC, it is assumed that when the variable resistance element MTJ in the breakdown state BD has the further low resistance value R_S3, the memory cell MC stores "0", and when the variable resistance element MTJ in the parallel state P has the low resistance value R_S2 and the variable resistance element MTJ in the anti-parallel state AP has the high the resistance value R_S1, the memory cell MC stores "1". In this state, the parallel state P and the anti-parallel state AP may be referred to as a non-breakdown state.

In the OMC, for example, in order to write "0" to the memory cell MC, the cell transistor CTj may be turned on, and a breakdown current flowing from the bit line BLj to the source line SLj may pass through the variable resistance element MTJ and the cell transistor CTj.

FIG. 2B illustrates an example of a reference cell according to some implementations.

The structure of the NRC in FIG. 2B may be applied to the NRC in FIG. 1. Content overlapping with the above-described content is omitted. When compared with the cell structure of FIG. 2A, the variable resistance element MTJ may be omitted from the NRC, and the NRC may be referred to as a shorted cell. In the following description with reference to FIGS. 2A and 2B together,

The NRC may include a reference cell transistor RT. The reference cell transistor RT may include a gate connected to the word line WLi, and a source and a drain respectively connected to a source line SLk and a bit line BLk. The reference cell transistor RT may electrically connect or disconnect the source line SLk and the bit line BLj according to the signal applied to the word line WLi.

A memory device (e.g., the memory device 10 of FIG. 1) may include a resistance circuit (e.g., the resistive element RM of reference switching circuits RSCa and RSCb in FIG. 4A and FIG. 4B) outside a cell array (e.g., the cell array 110 of FIG. 1), and in order to determine the value stored in the NMC, the resistance value of the variable resistance element MTJ may be compared with a resistance value (e.g., a resistance value of the resistive element RM in FIGS. 4A and 4B) of the resistance circuit based on the NRC that is a shorted cell. Hereinafter, while the NRC is assumed as a shorted cell as in the NRC in FIG. 2B, the disclosure is not limited thereto, and a reference cell including the variable resistance element MTJ operates in the same manner.

FIG. 3 is a graph showing dispersion of resistance values of the memory cell and the reference cell, according to some implementations.

FIG. 3 shows dispersion of resistance values of the NMC, the OMC, the NRC, and the OMC, according to some implementations. In FIG. 3, the horizontal axis indicates a resistance value R of a variable resistance element included in each cell, whereas the vertical axis indicates the number (count) of variable resistance elements having a corresponding resistance value.

Referring to FIG. 3, the NMC may have resistance values corresponding to a first state R_S1 and a second state R_S2. The first state R_S1 may correspond to a state having a relatively high resistance value, such as the anti-parallel state AP of the NMC or an amorphous state of a phase-change memory cell. The second state R_S2 may correspond to a state having a relatively low resistance value, such as the parallel state P of the NMC or a crystalline state of a phase-change memory cell. As the variable resistance element MTJ of the NMC is programmed to have one of the first state R_S1 and the second state R_S2, data may be stored. In the read operation, the NMC may provide a voltage or current corresponding to the resistance of a corresponding state of the first state R_S1 and the second state R_S2.

The NRC may have a reference state R_NRC. The reference state R_NRC may have a resistance value between the resistance value of the first state R_S1 and the resistance value of the second state R_S2. The reference state R_NRC may provide a voltage or current to enable identification of the first state R_S1 and the second state R_S2 in the read operation.

The OMC may have a resistance value corresponding to a third state R_S3. For example, the third state R_S3 may be achieved by breaking down (BD) the variable resistance element MTJ. For example, the OMC may include one valid variable resistance element MTJ. As one variable resistance element MTJ is connected to three OTP word lines, the variable resistance element MTJ may be broken down (BD) to easily have the third state R_S3 by using a further low voltage.

The ORC may have a reference state R_ORC. The reference state R_ORC may have a resistance value between the resistance value of the third state R_S3 and the resistance value of the second state R_S2. The reference state R_ORC may provide a voltage or current to enable identification of the third state R_S3 and the second state R_S2 in the read operation.

As an example, each of the three valid variable resistance elements MTJs of the ORC may be programmed to the second state R_S2. As the three valid variable resistance elements MTJs of the ORC are connected in parallel between a reference source line RSL and a reference bit line RBL, a total resistance value of the ORC may correspond to 1/3 of the resistance value of the second state R_S2. As each of the valid variable resistance elements MTJs of the ORC is programmed to the second state R_S2, the ORC may be implemented.

As an example, the ORC may be corrected to have two valid variable resistance elements MTJs. In this state, when the valid variable resistance elements MTJs of the ORC is programmed to the second state R_S2, the total resistance value of the ORC may be half the second state R_S2.

FIG. 4A is a diagram illustrating a cell array according to some implementations.

Referring to FIG. 4A, a cell array 110a may include the NMC, the OMC, the NRC, the ORC, and a reference switching circuit RSCa. In this state, a normal cell area NCA may include a normal memory area including a plurality of NMCs and a normal reference area including a plurality of NRCs. An OTP cell area OCA may include an OTP memory area including a plurality of OMCs and an OTP reference area including a plurality of ORCs. The cell array 110a of FIG. 4A may correspond to the cell array 110 of FIG. 1. The reference switching circuit RSCa of FIG. 4A may be used for a case in which any one of the NRC and the ORC generates a reference signal based on a fixed resistive element and the other generates a reference signal based on a combination of a plurality of cells. A method of generating a reference signal may be determined based on the read margin. For example, when the read margin is relatively large (e.g., in the case of the read operation of the NMC), a reference signal may be generated based on the fixed resistive element, and when the read margin is relatively small (e.g., in the case of the read operation of the OMC), a reference signal may be generated based on the combination of a plurality of cells. However, implementations of the disclosure are not limited thereto. Content overlapping with the above-described content is omitted.

The NMC may include the first variable resistance element MTJ1 and the first cell transistor CT1. A gate of the first cell transistor CT1 is connected to the word line WL, a drain of the first cell transistor CT1 is connected to one end of the first variable resistance element MTJ1, and a source of the first cell transistor CT1 is connected to a source line SL. The other end of the first variable resistance element MTJ1 is connected to the bit line BL.

The OMC may have a different structure from the NMC. In some implementations, the number of the second cell transistors CT2 included in the OMC may be greater than the number of the first cell transistors CT1 included in the NMC. The NMC may include one first variable resistance element MTJ1 and two first cell transistors CT1. A 2T-1R structure in which one NMC is connected to two first cell transistors CT1 may constitute one unit NMC in the cell array 110a.

The OMC may include the second variable resistance element MTJ2 and the second cell transistor CT2. A gate of the second cell transistor CT2 is connected to the word line WL, a drain of the second cell transistor CT2 is connected to one end of the second variable resistance element MTJ2, and a source of the second cell transistor CT2 is connected to the source line SL. The other end of the second variable resistance element MTJ2 is connected to the bit line BL.

The OMC may include one second variable resistance element MTJ2 and six second cell transistors CT2. The second cell transistors CT2 may be connected in parallel to the second variable resistance element MTJ2. The second cell transistors CT2 may apply, to the OMC, the higher breakdown current than the typical write current. A 6T-1R structure in which one OMC is connected to six second cell transistors CT2 may constitute one unit OMC in the cell array 110a. In the 6T-1R structure, as the higher voltage value is applied to the second variable resistance element MTJ2 compared with the second cell transistor CT2, the second variable resistance element MTJ2 may be easily changed to the breakdown state BD. However, this is merely an example, and the disclosure is not limited thereto.

In some implementations, the OMC may have the same structure as the NMC. As an example, a 1T-1R structure in which one NMC is connected to one first cell transistor CT1 may constitute one unit NMC in the cell array 110a, and a 1T-1R structure in which one OMC is connected to one second cell transistor CT2 may constitute one unit OMC in the cell array 110a. However, the disclosure is not limited thereto, and the NMC and the OMC may have various structures, for example, a 2T-2R structure in which two neighboring memory cells (NMC and OMC) are commonly connected to two cell transistors CT.

A cell array 110b may include dummy cells DC, and each dummy cell DC may be connected neither to corresponding second cell transistor CT2 and word lines, nor to corresponding bit line BL and source line SL.

The NRC, as illustrated in FIG. 2B, may include a third cell transistor CT3 while omitting the variable resistance element MTJ. A gate of the third cell transistor CT3 is connected to the word line WL, a drain of the third cell transistor CT3 is connected to the reference bit line RBL, and a source of the third cell transistor CT3 is connected to the reference source line RSL.

The ORC may include a third variable resistance element MTJ3 and a fourth cell transistor CT4. A gate of the fourth cell transistor CT4 is connected to the word line WL, a drain of the fourth cell transistor CT4 is connected to one end of the third variable resistance element MTJ3, and a source of the fourth cell transistor CT4 is connected to the reference source line RSL. The other end of the third variable resistance element MTJ3 is connected to the reference bit line RBL.

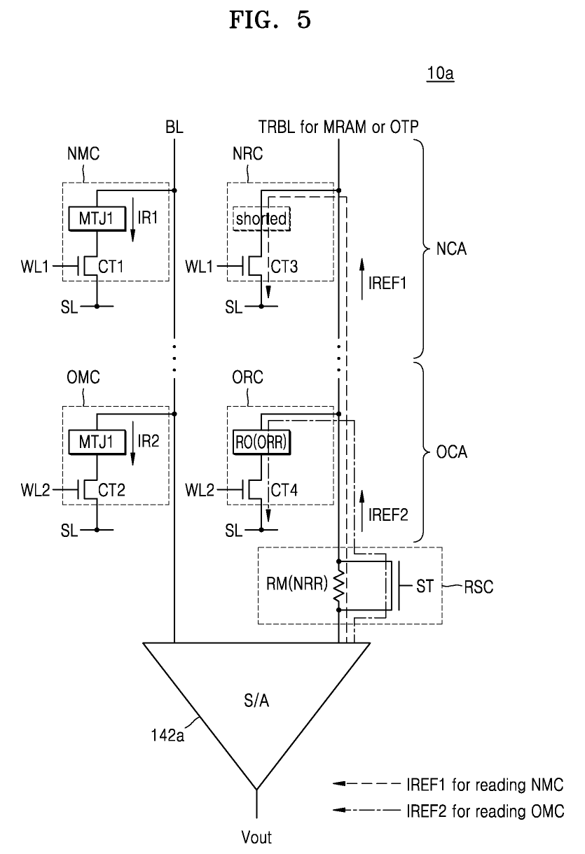

The reference switching circuit RSCa may include the resistive element RM and a switch transistor ST. The resistive element RM and the switch transistor ST are connected in parallel to each other, and connected to the reference bit line RBL. The switch transistor ST is turned on or off according to the control signal of the controller 170. The controller 170 may generate different control signals depending on whether a read operation is the read operation of the NMC or the read operation of the OMC. In other words, the controller 170 may generate different control signals depending on the type of the memory cell. In the read operation of the NMC, the switch transistor ST may be turned off according to the first control signal of the controller 170. In this state, a resistance value (e.g., a resistance value NRR of the resistive element RM in FIG. 5) of the resistive element RM may correspond to the resistance value of the NRC. In the read operation of the ORC, the switch transistor ST may be turned on according to the second control signal of the controller 170. In this state, the resistive element RM is bypassed, and a resistance value (e.g., a second reference resistance value ORR of a resistive element RO in FIG. 5) that is generated by connecting/combining the ORCs (e.g., the variable resistance elements of the ORCs) (see FIG. 3) may correspond to the resistance value of the ORC.

FIG. 4B is a diagram illustrating a cell array according to some implementations.

Referring to FIG. 4B, the cell array 110b may include the NRC, the ORC, and a reference switching circuit RSCb. Compared with FIG. 4A, as the method of generating an OTP reference resistance value is changed from FIG. 4B, the structure of the reference switching circuit RSCb may be different from the structure of the ORC. The cell array 110b of FIG. 4B may correspond to the cell array 110 of FIG. 1. The reference switching circuit RSCb of FIG. 4B may be used when the NRC and the ORC both generate reference signals based on the fixed resistive element. Content overlapping with the above-described content is omitted.

The method of generating the OTP reference resistance value of FIG. 4B may be different from the method of FIG. 4A. The method of generating the OTP reference resistance value in FIG. 4A is a method of generating a reference resistance value by connecting/combining the ORCs (e.g., the variable resistance elements of the ORCs). In contrast, the method of generating the OTP reference resistance value in FIG. 4B is a method of generating a reference resistance value based on a fixed resistance value (e.g., the second reference resistance value ORR) of the variable resistance element RO. The method of generating a normal reference resistance value is the method of generating a reference resistance value based on the fixed resistance value (e.g., the resistance value NRR) of the resistive element RM, and is identical in FIGS. 4A and 4B.

Due to the different methods of generating the OTP reference resistance value, the structure of the ORC in FIG. 4A may be different from the structure of the ORC in FIG. 4B. For example, the structure of the ORC in FIG. 4A may have the structure illustrated in FIG. 2A, and the structure of the ORC in FIG. 4B may have the structure illustrated in FIG. 2B. As the descriptions about the NMC, the OMC, the NRC are redundant to those presented in FIG. 4A, descriptions thereof are omitted.

The NRC, as illustrated in FIG. 2B, may include the third cell transistor CT3 while omitting the variable resistance element MTJ. A gate of the third cell transistor CT3 is connected to the word line WL, a drain of the third cell transistor CT3 is connected to the reference bit line RBL, and a source of the third cell transistor CT3 is connected to the reference source line RSL.

The ORC, as illustrated in FIG. 2B, may include the fourth cell transistor CT4 while omitting the variable resistance element MTJ. A gate of the fourth cell transistor CT4 is connected to the word line WL, a drain of the fourth cell transistor CT4 is connected to the reference bit line RBL, and a source of the fourth cell transistor CT4 is connected to the reference source line RSL.

Due to the different methods of generating the OTP reference resistance value, the structure of the switching circuit RSCb of FIG. 4B may be different from the structure of the switching circuit RSCa of FIG. 4A. Unlike the switching circuit RSCa of FIG. 4A, the switching circuit RSCb may include the resistive element RM, the variable resistance element RO, and a switch element SW. The switch element SW may be connected to any one of the resistive element RM and the variable resistance element RO according to the control signal of the controller 170. The controller 170 may generate different control signals depending on whether a read operation is the read operation of the NMC or the read operation of the OMC. In other words, the controller 170 may generate different control signals according to the type of the memory cell. In the read operation of the NMC, the switch element SW may be connected to the resistive element RM according to the first control signal of the controller 170. In this state, the resistance value (e.g., the resistance value NRR of the resistive element RM in FIG. 5) of the resistive element RM may correspond to the resistance value of the NRC. In the read operation of the ORC, the switch element SW may be connected to the variable resistance element RO according to the second control signal of the controller 170. In this state, a resistance value (e.g., the second reference resistance value ORR of the variable resistance element RO in FIG. 5) of the variable resistance element RO may correspond to the resistance value of the ORC.

Referring to FIGS. 4A and 4B, the NRC and the ORC according to some implementations may share the reference bit line RBL based on the reference switching circuits RSCa and RSCb. In the disclosure, the reference bit line RBL shared by the NRC and the ORC may be referred to as a target reference bit line.

As the NRC and the ORC according to some implementations share the reference bit line RBL, a separate bit line for the ORC is not added, and thus an increase in the size of the core area of the memory device 10 may be prevented. Furthermore, by preventing deterioration of word line offset properties occurring when a separate reference bit line for the ORC is arranged, the read margin of the memory device 10 may be improved.

FIG. 5 is a diagram illustrating a structure of a memory device 10a in a read operation of the memory device, according to some implementations.

In detail, FIG. 5 is an equivalent circuit diagram schematically illustrating a structure of the memory device 10a in the read operation of the NMC and the OMC, and the memory device 10a of FIG. 5 may correspond to the memory device 10 of FIG. 1. Content overlapping with the above-described content is omitted.

Referring to FIG. 5, the memory device 10a may include a sense amplifier 142a, the NMC, the OMC, the NRC, the NMC, and the reference switching circuit RSC. The sense amplifier 142a may be included in the read circuit 140 of FIG. 1. In FIG. 5, descriptions are based on an assumption that the sense amplifier 142a is a voltage sense amplifier. Furthermore, although FIG. 5 assumes that the NRC is a shorted cell, the disclosure is not limited thereto.

The memory device 10a may include the reference switching circuit RSC connected to the NRC and the ORC outside the cell array. The reference switching circuit RSC may include the resistive element RM and the switch transistor ST. The NRC and the ORC may be connected to the reference switching circuit RSC through the shared reference bit line (i.e., a target reference bit line TRBL). The reference switching circuit RSC may turn off the switch transistor ST according to the control signal of the controller 170 to connect the NRC to the resistive element RM. The reference switching circuit RSC may turn on the switch transistor ST according to a control signal to bypass the resistive element RM and connect the ORC to the switch transistor ST. The NRC and the ORC may transmit the generated reference signal to the sense amplifier 142a through the shared reference bit line (i.e., the target reference bit line TRBL). When the sense amplifier 142a is a voltage sense amplifier, a reference signal may indicate a reference voltage value corresponding to each of the NRC and the ORC.

The NRC and the NMC may be included in the normal cell area NCA of the cell array of the memory device 10a, and connected to the same the word line WL1. In FIG. 5, descriptions are based on an assumption that the NRC and the NMC are connected to the word line WL1. The NMC may include the first cell transistor CT1 and the first variable resistance element MTJ1. The NRC may be a shorted cell, and may include a third cell transistor (i.e., reference cell transistor) CT3.

The memory device 10a may include the reference switching circuit RSC connected to the NRC outside the cell array. The NRC may have a first reference resistance value NRR. That the NRC has the first reference resistance value NRR may mean that the reference switching circuit RSC (i.e., the resistive element RM of the reference switching circuit RSC) connected to the NRC has the first reference resistance value NRR. As an example, the first reference resistance value NRR may be a resistance value to distinguish the parallel state from anti-parallel state of the NMC. The data stored in the NMC may be read based on the first reference resistance value NRR.

In the read operation of the NMC, the read circuit 140 of FIG. 1 may provide a preset electrical signal to each of the NMC and the NRC by using the current generator. The current generator may provide a first current IR1 to the NMC and a first reference current IREF1 to the NRC. In this state, the first reference current IREF1 provided to the NRC may flow from a positive supply voltage (e.g., VDD) to a negative supply voltage (e.g., VSS) by passing through the NRC and the resistive element RM of the reference switching circuit RSC, and the first current IR1 provided to the NMC may flow from the positive supply voltage VDD to the negative supply voltage VSS by passing through the NMC.

The sense amplifier 142a, in the read operation of the NMC, may determine the value stored in the NMC by detecting a difference between a first input signal applied from the NMC (e.g., a read voltage value applied from the NMC) and a first reference signal applied from the NRC (e.g., a reference voltage value applied from the NRC), based on the first current IR1. The sense amplifier 142a may detect a difference between the first input signal that is a voltage of the NMC based on the first current IR1 and the first reference signal that is a voltage of a normal reference cell based on the first reference current IREF1. The sense amplifier 142a may receive the first reference signal that is a voltage of a normal reference cell through the reference bit line RBL (i.e., the target reference bit line TRBL).

The sense amplifier 142a may generate a comparison signal (i.e., a difference value between the read voltage value applied from the NMC and the reference voltage value applied from the NRC) by comparing the first reference signal by the NRC and the resistive element RM of the reference switching circuit RSC and the first input signal by the NMC. The comparison signal may represent the value stored in the NMC. The memory device 10a may generate a data signal V_OUT representing the value stored in the NMC based on the comparison signal.

The OMC and the ORC may be included in the OTP cell area OCA of the cell array of the memory device 10a, and connected to the same word line WLn. The sense amplifier 142a may be connected to the OMC and the ORC. In FIG. 5, descriptions are based on an assumption that the ORC and the OMC are connected to the word line WLn. The OMC may include the second cell transistor CT2 and the second variable resistance element MTJ2. The ORC may include the variable resistance element RO and the fourth cell transistor CT4. The variable resistance element RO may be a resistive element generated by combining/connecting the variable resistance elements MTJs of the ORCs. The ORC may have a second reference resistance value ORR. That the ORC has the second reference resistance value ORR may mean that the variable resistance element RO of the ORC has the second reference resistance value ORR. For example, as three valid variable resistance elements MTJs of the ORC are combined/connected in parallel between the reference source line RSL and the reference bit line RBL, the resistance value of the variable resistance element RO may correspond to 1/3 of the resistance value of the parallel state P (in this state, each of the three valid variable resistance elements MTJs is assumed to be programmed to the parallel state P). In this state, the second reference resistance value ORR of the ORC may be 1/3 of the resistance value of the parallel state P corresponding to the resistance value of the variable resistance element RO.

As an example, the second reference resistance value ORR may be a resistance value to distinguish the breakdown state from the parallel state P of the OMC. However, the disclosure is not limited thereto, and the second reference resistance value ORR may be a resistance value to distinguish the breakdown state from the anti-parallel state AP of the OMC. The data stored in the OMC may be read based on the second reference resistance value ORR.

In the read operation of the OMC, the read circuit 140 of FIG. 1 may provide, by using the current generator, a second current IR2 to the OMC and a second reference current IREF2 to the ORC. As illustrated in FIG. 5, the second reference current IREF2 provided to the ORC may flow from the positive supply voltage VDD to the negative supply voltage VSS by passing through the ORC and the switch transistor ST of the reference switching circuit RSC (i.e., by passing the resistive element RM of the reference switching circuit RSC). Furthermore, the second current IR2 may flow from the positive supply voltage VDD to the negative supply voltage VSS by passing through the OMC.

The sense amplifier 142a may determine the value stored in the OMC by detecting a difference between a second input signal applied from the OMC based on the second current IR2 (e.g., a read voltage value applied from the OMC), and a second reference signal applied from the ORC based on the second reference current IREF2 (e.g., a reference voltage value applied from the ORC). The sense amplifier 142a may generate a comparison signal (i.e., a difference value between a read voltage value applied from the OMC and a reference voltage value applied from the ORC) by comparing the second reference signal that is a voltage by the ORC, and the second input signal that is a voltage by the OMC. The comparison signal may represent the value stored in the OMC. The memory device 10a may generate the data signal V_OUT representing the value stored in the OMC based on the comparison signal.

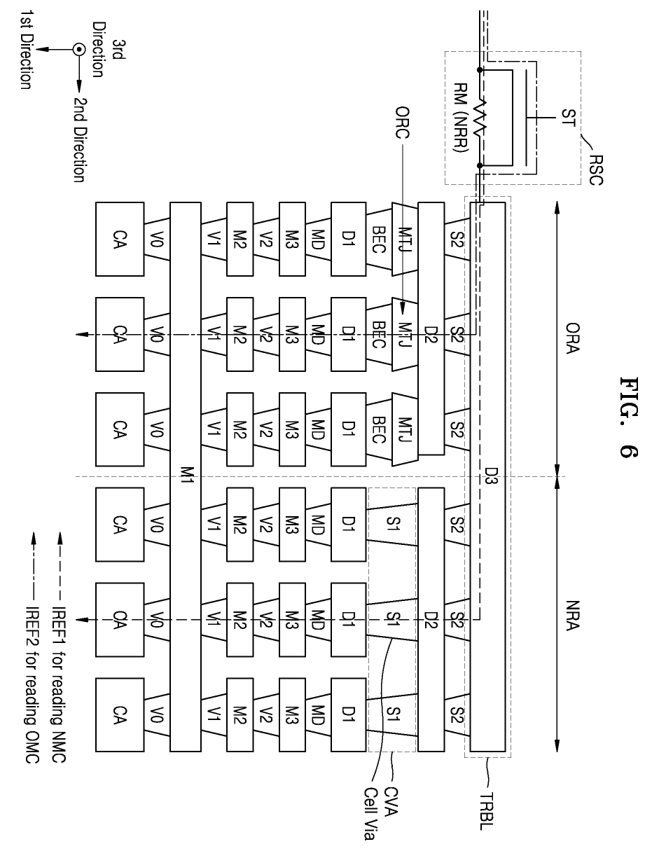

FIGS. 6 to 9 which are described below illustrate a wiring structure for the NRC and the ORC to share the target reference bit line TRBL based on the reference switching circuit RSC according to some implementations.

FIG. 6 is a diagram illustrating a wiring structure associated with a reference bit line and a reference cell of a memory device according to some implementations.

In FIG. 6, it is assumed that the reference resistance value of the NRC is generated based on a fixed resistance value, and the reference resistance value of the ORC is generated based on the connection/combination of the ORCs (e.g., the variable resistance elements of the ORCs). Content overlapping with the above-described content is omitted.

Referring to FIG. 6, the bit line and the source line of the memory device may extend in a second direction. A reference bit line D3 may be connected to the reference switching circuit RSC and may extend in the second direction. In this state, the reference bit line D3, which is shared by the NRC and the ORC, may correspond to the target reference bit line TRBL. A bit line D2 and a source line M1 may extend in the second direction. However, the disclosure is not limited thereto, and according to some implementations, the bit line D2 may be omitted.

In the normal cell area NCA, a via (e.g., S1, S2, MD, V2, V1, or V0 in FIG. 6) may connect a bit line to bit line (e.g., D2 or D3 in FIG. 6), a bit line / a source line (e.g., M1 in FIG. 6) to a metal (e.g., D1, M2, or M3 in FIG. 6), or a metal to another metal. In particular, as a plurality of cell vias S1s are formed under the reference bit line D3 in the normal cell area NCA (e.g., the cell vias S1s are formed in a cell via area CVA of FIG. 6), the first reference current IREF1 may generate the first reference signal without passing through the NRC. In other words, the first reference signal may be generated based on the fixed resistance value NRR of the resistive element RM by using the cell via S1. For example, the reference bit line D3 and the bit line D2 may be connected by the via S2, the bit line D2 and the metal D1 may be connected by the cell via S1, the metal D1 and the metal M3 may be connected by the via MD, and the source line M1 and a contact CA may be connected by the via V0.

In the OTP cell area OCA, the via (e.g., S1, S2, MD, V2, V1, or V0 in FIG. 6) may connect the bit line to the bit line (e.g., D2 or D3 in FIG. 6), the bit line / the source line (e.g., M1 in FIG. 6) to the metal, or a metal to another metal (e.g., D1, M2, or M3 in FIG. 6). Content overlapping with the above-described content is omitted. In the OTP cell area OCA, the ORC and the metal may be connected to each other by a contact BEC.

In the read operation of the NMC, (as the switch transistor ST is turned off according to the control signal) the first reference current IREF1 provided by the read circuit 140 of FIG. 1 may pass through the NRC and the resistive element RM and generate the first reference signal. The resistance value NRR of the resistive element RM may correspond to the reference resistance value of the NRC. The sense amplifier 142 may determine the value stored in the NMC by detecting the difference between the first input signal applied from the NMC and the first reference signal applied from the NRC. The sense amplifier 142 may generate the comparison signal by comparing the first reference signal by the NRC and the resistive element RM with the first input signal by the NMC. The comparison signal may represent the value stored in the NMC. The memory device 10 may generate the data signal representing the value stored in the NMC from the comparison signal.

In the read operation of the ORC, (as the switch transistor ST is turned on according to the control signal) the second reference current IREF2 provided by the read circuit 140 may bypass the resistive element RM and the ORC and generate the second reference signal. In this state, the resistance value of the variable resistance element of the ORC may be a resistance value generated by connecting/combining the ORCs (e.g., the variable resistance elements of the ORCs) (see FIG. 3). The sense amplifier 142 may determine the value stored in the OMC by detecting the difference between the second input signal applied from the OMC and the second reference signal applied by the ORC. The sense amplifier 142 may generate the comparison signal by comparing the second reference signal by the connection/combination of the ORCs with the second input signal by the OMC. The comparison signal may represent the value stored in the OMC. The memory device 10 may generate the data signal representing the value stored in the OMC from comparison signal.

According to some implementations, in the wiring structure of the normal cell area NCA, as the cell via S1s are formed under the target reference bit line TRBL (i.e., the reference bit line D3), the first reference current IREF1 may generate the first reference signal by passing through the resistive element RM, without passing through the NRC. In other words, the NRC may generate the first reference signal based on the fixed resistive element (e.g., the resistive element RM) through the cell vias S1s. To this end, while omitting the variable resistance element MTJ of the NRC, the NRC may be implemented as a shorted cell (see FIG. 2B). In the wiring structure of the OTP cell area OCA, as the ORCs are arranged under the target reference bit line TRBL (i.e., the reference bit line D3), the second reference current IREF2 may pass through the switch transistor ST (by passing the resistive element RM) and the OTP reference cell to generate the second reference signal. In other words, the memory device may generate the reference signal by different methods depending on whether a read operation is the read operation of the NMC or the read operation of the OMC.

In the memory device according to some implementations, by sharing the target reference bit line TRBL between the NRC and the ORC, the NMC and the OMC may be included in an IP block (or one memory chip). Furthermore, the memory device may increase the read margin of each memory cell by varying the generation method of the reference signal (e.g., a generation method based on a fixed resistance value / a hybrid generation method based on a connection/combination of a plurality of reference cells) depending on the type of the memory cell (e.g., the NMC/the OMC), though the cell vias S1s connected to the target reference bit line TRBL.

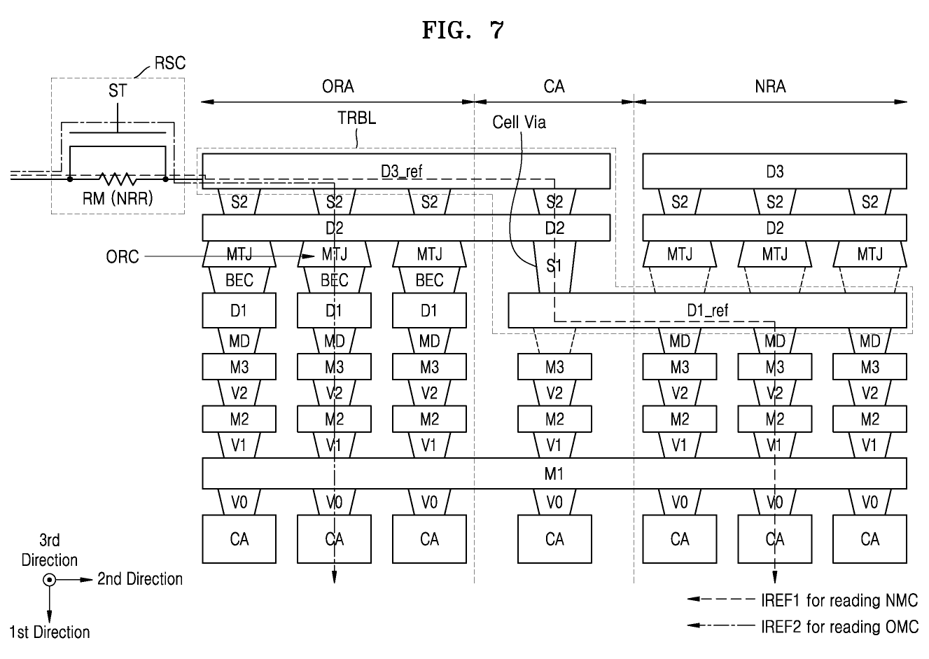

FIG. 7 is a diagram illustrating a wiring structure associated with a reference bit line and a reference cell of a memory device according to some implementations.

In FIG. 7, it is assumed that the reference resistance value of the NRC is generated based on the fixed resistance value, and the reference resistance value of the ORC is generated based on the connection/combination of the ORCs (e.g., the variable resistance elements of the ORCs). Content overlapping with the above-described content is omitted.

Referring to FIG. 7, the bit line and the source line of the memory device may extend in the second direction. A reference bit line D3_ref may be connected to the reference switching circuit RSC to extend to a connection area CA in the second direction. In this state, the reference bit line D3_ref may form a part of the target reference bit line TRBL shared by the NRC and the ORC (e.g., a first reference bit line of the target reference bit line TRBL).

In the normal cell area NCA, a via (e.g., S2, MD, V2, V1, or V0 in FIG. 7) may connect a bit line to another bit line (e.g., D2 or D3 in FIG. 7), a bit line / a source line (e.g., M1 in FIG. 7) to a metal (e.g., D1, M2, or M3 in FIG. 7), or a metal to another metal. For example, the reference bit line D1_ref and the metal M3 may be connected to each other by the via MD, and the source line M1 and the contact CA may be connected to each other by the via V0.

In the OTP cell area OCA, the via (e.g., S2, MD, V2, V1, or V0 in FIG. 7) may connect a bit line to another bit line (e.g., D2 or D3_ref in FIG. 7), a bit line / a source line (e.g., M1 in FIG. 7) to a metal, or a metal to another metal (e.g., D1, M2, or M3 in FIG. 7). Content overlapping with the above-described content is omitted. In the OTP cell area OCA, the ORC and the metal may be connected to each other through the contact BEC.

The connection area CA may represent an area between the normal reference cell and the OTP reference cell (i.e., an area between a normal reference area NRA and an OTP reference area ORA). In the connection area CA, as the cell via S1 is formed under the bit line D2, the reference bit line D3_ref and the reference bit line D1_ref may be connected to each other by the cell via S1. In this state, the reference bit line D3_ref and the reference bit line D1_ref may be arranged on different layers. The reference bit line D1_ref may form a part of the target reference bit line TRBL shared by the NRC and the ORC (e.g., a second reference bit line of the target reference bit line TRBL). The reference bit line D3_ref may be connected to the reference bit line D1_ref through the cell via S1, thereby forming the target reference bit line TRBL. The first reference current IREF1 may generate a first reference signal, without passing through the NRC, based on the target reference bit line TRBL formed based on the cell via S1. In other words, the first reference signal may be generated based on the fixed resistance value NRR of the resistive element RM, by using the cell via S1. In FIG. 7, for convenience of explanation, one cell via S1 is illustrated, but the disclosure is not limited thereto, and the cell via S1 according to some implementations may be formed in various numbers according to implementations.

In the read operation of the NMC, (as the switch transistor ST is turned off according to the control signal) the first reference current IREF1 provided by the read circuit 140 of FIG. 1 may generate the first reference signal by passing through the NRC and the resistive element RM. The resistance value NRR of the resistive element RM may correspond to the reference resistance value of the NRC. The sense amplifier 142 may determine the value stored in the NMC by detecting the difference between the first input signal applied from the NMC and the first reference signal applied from the NRC. The sense amplifier 142 may generate the comparison signal by comparing the first reference signal by the NRC and the resistive element RM with the first input signal by the NMC. The comparison signal may represent the value stored in the NMC. The memory device 10 may generate the data signal representing the value stored in the NMC from the comparison signal.

In the read operation of the ORC, (as the switch transistor ST is turned on according to the control signal) the second reference current IREF2 provided by the read circuit 140 may bypass the resistive element RM and the ORC and generate the second reference signal. In this state, the resistance value of the variable resistance element of the ORC may be a resistance value generated by connecting/combining the ORCs (e.g., the variable resistance elements of the ORCs) (see FIG. 3). The sense amplifier 142 may determine the value stored in the OMC by detecting the difference between the second input signal applied from the OMC and the second reference signal applied by the ORC. The sense amplifier 142 may generate the comparison signal by comparing the second reference signal by the connection/combination of the ORCs with the second input signal by the OMC. The comparison signal may represent the value stored in the OMC. The memory device 10 may generate the data signal representing the value stored in the OMC from comparison signal.

In the wiring structure of the connection area CA according to some implementations, as the cell via S1 is formed under the bit line D2, the reference bit line D3_ref and the reference bit line D1_ref may be connected to each other through the cell via S1, thereby forming the target reference bit line TRBL. The first reference current IREF1 may generate the first reference signal by passing through the resistive element RM, without passing through the NRC, by using the cell via S1. In the wiring structure of the OTP cell area OCA, as the ORCs are arranged under the reference bit line D3_ref, the second reference IREF2 may generate the second reference signal by passing through the switch transistor ST (bypassing the resistive element RM) and passing through the OTP reference cell. In other words, the memory device may generate the reference signal by different methods depending on whether a read operation is the read operation of the NMC or the read operation of the OMC.

The memory device according to some implementations may include the NMC and the OMC in an IP block (or one memory chip) by forming the target reference bit line TRBL through the cell via S1 of the connection area, and by sharing the target reference bit line TRBL between the NRC and the ORC. Furthermore, the memory device may increase the read margin of each memory cell by varying the generation method of the reference signal (e.g., a generation method based on a fixed resistance value / a hybrid generation method based on a connection/combination of a plurality of reference cells) depending on the type of the memory cell, through the cell via S1 connected to the target reference bit line TRBL.

FIG. 8 is a diagram illustrating a wiring structure associated with a reference bit line and a reference cell of a memory device according to some implementations.

In FIG. 8, it is assumed that the reference resistance value of the NRC is generated based on the fixed resistance value, and the reference resistance value of the ORC is generated based on the connection/combination of the ORCs (e.g., the variable resistance elements of the ORCs). Content overlapping with the above-described content is omitted.

Referring to FIG. 8, the bit line and the source line of the memory device may extend in the second direction. The reference bit line D3_ref may be connected to the reference switching circuit RSC to extend to the connection area CA in the second direction. In this state, the reference bit line D3_ref may form a part of the target reference bit line TRBL shared by the NRC and the ORC (e.g., the first reference bit line of the target reference bit line TRBL).

In the normal cell area NCA, a via (e.g., S2, MD, V2, V1, or V0 in FIG. 8) may connect a bit line to another bit line (e.g., D2 or D3 in FIG. 8), a bit line / a source line (e.g., M1 in FIG. 8) to a metal (e.g., D1, M2, or M3 in FIG. 8), or a metal to another metal. For example, the reference bit line D1_ref and the metal M3 may be connected to each other by the via MD, and the source line M1 and the contact CA may be connected to each other by the via V0.

In the OTP cell area OCA, the via (e.g., S2, MD, V2, V1, or V0 in FIG. 8) may connect a bit line to another bit line (e.g., D2 or D3_ref in FIG. 8), a bit line / a source line (e.g., M1 in FIG. 8) to a metal, or a metal to another metal (e.g., D1, M2, or M3 in FIG. 8). Content overlapping with the above-described content is omitted. In the OTP cell area OCA, the ORC may be connected to a metal through the contact BEC.

The connection area CA may represent the area between the normal reference cell and the OTP reference cell (i.e., the area between the normal reference area NRA and the OTP reference area ORA). In the connection area CA, as the first BCCs are formed under the bit line D2, the reference bit line D3_ref and the reference bit line D1 may be connected to each other through the first BCCs. The first BCCs may each include the variable resistance element MTJ. Each of the first BCCs and the reference bit line D1_ref may be connected to each other through the contact BEC. As an example, as the first BCCs are connected in parallel to the bit line D2 and the reference bit line D1_ref, the resistance value of the variable resistance element included in each of the first BCCs may relatively decrease. The first BCCs may each have a relatively small resistance value so as to correspond to the cell vias S1s of FIG. 6. In order to prevent I/O offset, before the read operation of the memory device, the controller 170 may preset all of the first BCCs to a parallel state or an anti-parallel state.

The reference bit line D1_ref may form a part of the target reference bit line TRBL shared by the NRC and the ORC (e.g., the second reference bit line of the target reference bit line TRBL). In this state, the reference bit line D3_ref and the reference bit line D1_ref may be arranged on different layers. The reference bit line D3_ref and the reference bit line D1_ref may be connected to each other through the first BCCs, thereby forming the target reference bit line TRBL. The first reference current IREF1 may generate a first reference signal, without passing through the NRC, through target reference bit line TRBL formed based on the first BCCs that are connected in parallel. In other words, the first reference signal may be generated based on the fixed resistance value NRR of the resistive element RM, by using the first BCCs. In FIG. 7, for convenience of explanation, three first BCCs are illustrated as being connected in parallel, but the disclosure is not limited thereto, and the first BCCs according to some implementations may be arranged in various numbers and shapes according to implementations.

In the read operation of the NMC, (as the switch transistor ST is turned off according to the control signal) the first reference current IREF1 provided by the read circuit 140 of FIG. 1 may generate the first reference signal by passing through the NRC and the resistive element RM. The resistance value NRR of the resistive element RM may correspond to the reference resistance value of the NRC. The sense amplifier 142 may determine the value stored in the NMC by detecting the difference between the first input signal applied from the NMC and the first reference signal applied from the NRC. The sense amplifier 142 may generate the comparison signal by comparing the first reference signal by the NRC and the resistive element RM with the first input signal by the NMC. The comparison signal may represent the value stored in the NMC. The memory device 10 may generate the data signal representing the value stored in the NMC from the comparison signal.

In the read operation of the ORC, (as the switch transistor ST is turned on according to the control signal) the second reference current IREF2 provided by the read circuit 140 may bypass the resistive element RM and the ORC and generate the second reference signal. In this state, the resistance value of the variable resistance element of the ORC may be a resistance value generated by connecting/combining the ORCs (e.g., the variable resistance elements of the ORCs) (see FIG. 3). The sense amplifier 142 may determine the value stored in the OMC by detecting the difference between the second input signal applied from the OMC and the second reference signal applied by the ORC. The sense amplifier 142 may generate the comparison signal by comparing the second reference signal by the connection/combination of the ORCs with the second input signal by the OMC. The comparison signal may represent the value stored in the OMC. The memory device 10 may generate the data signal representing the value stored in the OMC from comparison signal.

In the wiring structure of the connection area CA according to some implementations, as the first BCCs are formed under the bit line D2, the reference bit line D3_ref and the reference bit line D1_ref may be connected to each other through the first BCCs, thereby forming the target reference bit line TRBL. The first reference current IREF1 may generate the first reference signal by passing through the resistive element RM, without passing through the NRC, by using the first BCCs. In the wiring structure of the OTP cell area OCA, as the ORCs are arranged under the reference bit line D3_ref, the second reference current IREF2 may generate the second reference signal by passing through the switch transistor ST (bypassing the resistive element RM) and passing through the OTP reference cell. In other words, the memory device may generate the reference signal by different methods depending on whether a read operation is the read operation of the NMC or the read operation of the OMC.

The memory device according to some implementations may form the target reference bit line TRBL through the cell via S1 of the connection area, and the NMC and the OMC may be included in an IP block (or one memory chip) by sharing the target reference bit line TRBL between the NRC and the ORC. Furthermore, the memory device may increase the read margin of each memory cell by varying the generation method of the reference signal (e.g., a generation method based on a fixed resistance value / a hybrid generation method based on a connection/combination of a plurality of reference cells) depending on the type of the memory cell, through the first BCCs connected to the target reference bit line TRBL.

FIG. 9 is a diagram illustrating a wiring structure associated with a reference bit line and a reference cell of a memory device according to some implementations.

In FIG. 9, it is assumed that the reference resistance value of the NRC is generated based on the fixed resistance value, and the reference resistance value of the ORC is generated based on the connection/combination of the ORCs (e.g., the variable resistance elements of the ORCs). Content overlapping with the above-described content is omitted.

Referring to FIG. 9, the bit line and the source line of the memory device may extend in the second direction. The reference bit line D3_ref may be connected to the reference switching circuit RSC to extend to the connection area CA in the second direction. In this state, the reference bit line D3_ref may form a part of the target reference bit line TRBL shared by the NRC and the ORC (e.g., the first reference bit line of the target reference bit line TRBL).

In the normal cell area NCA, a via (e.g., S2, MD, V2, V1, or V0 in FIG. 9) may connect a bit line to another bit line (e.g., D2 and D3 in FIG. 9), a bit line / a source line (e.g., M1 in FIG. 9) to a metal (e.g., D1, M2, or M3 in FIG. 9), or a metal to another metal. For example, the reference bit line D1_ref and the metal M3 may be connected to each other by the via MD, and the source line M1 and the contact CA may be connected to each other by the via V0.

In the OTP cell area OCA, the via (e.g., S2, MD, V2, V1, or V0 in FIG. 9) may connect a bit line to another bit line (e.g., D2 and D3_ref in FIG. 9), a bit line / a source line (e.g., M1 in FIG. 9) to a metal, or a metal to another metal (e.g., D1, M2, or M3 in FIG. 9). Content overlapping with the above-described content is omitted. In the OTP cell area OCA, the ORC may be connected to a metal through the contact BEC.

The connection area CA may represent the area between the normal reference cell and the OTP reference cell (i.e., the area between the normal reference area NRA and the OTP reference area ORA). In the connection area CA, as the second BCC is formed under the bit line D2, the reference bit line D3_ref and the reference bit line D1_ref may be connected to each other through the second BCC. The second BCC may each include the variable resistance element MTJ. The second BCC and the reference bit line D1_ref may be connected to each other through the contact BEC. As an example, as the second BCC is preset to a breakdown state (i.e., the second BCC is shorted), the resistance value of the variable resistance element included in the second BCC may relatively decrease. The second BCC having a relatively small resistance value may correspond to the cell via S1 of FIG. 7. The controller 170 may apply a predetermined amount of high bias to the second BCC so that the second BCC is preset to a breakdown state (i.e., the second BCC to a shorted state).

The reference bit line D1_ref may form a part of the target reference bit line TRBL shared by the NRC and the ORC (e.g., the second reference bit line of the target reference bit line TRBL). In this state, the reference bit line D3_ref and the reference bit line D1_ref may be arranged on different layers. The reference bit line D3_ref and the reference bit line D1_ref may be connected to each other through the second BCC, thereby forming the target reference bit line TRBL. The first reference current IREF1 may generate a first reference signal, without passing through the NRC, based on the target reference bit line TRBL formed based on the second BCC. In other words, the first reference signal may be generated based on the fixed resistance value NRR of the resistive element RM, by using the second BCC. In FIG. 7, for convenience of explanation, one second BCC is illustrated, the disclosure is not limited thereto, and according to some implementations, the second BCC may be arranged in various numbers according to implementations.

In the read operation of the NMC, (as the switch transistor ST is turned off according to the control signal) the first reference current IREF1 provided by the read circuit 140 of FIG. 1 may generate the first reference signal by passing through the NRC and the resistive element RM. The resistance value NRR of the resistive element RM may correspond to the reference resistance value of the NRC. The sense amplifier 142 may determine the value stored in the NMC by detecting the difference between the first input signal applied from the NMC and the first reference signal applied from the NRC. The sense amplifier 142 may generate the comparison signal by comparing the first reference signal by the NRC and the resistive element RM with the first input signal by the NMC. The comparison signal may represent the value stored in the NMC. The memory device 10 may generate the data signal representing the value stored in the NMC from the comparison signal.

In the read operation of the ORC, (as the switch transistor ST is turned on according to the control signal) the second reference current IREF2 provided by the read circuit 140 may bypass the resistive element RM and the ORC and generate the second reference signal. In this state, the resistance value of the variable resistance element of the ORC may be a resistance value generated by connecting/combining the ORCs (e.g., the variable resistance elements of the ORCs) (see FIG. 3). The sense amplifier 142 may determine the value stored in the OMC by detecting the difference between the second input signal applied from the OMC and the second reference signal applied by the ORC. The sense amplifier 142 may generate the comparison signal by comparing the second reference signal by the connection/combination of the ORCs with the second input signal by the OMC. The comparison signal may represent the value stored in the OMC. The memory device 10 may generate the data signal representing the value stored in the OMC from comparison signal.

In the wiring structure of the connection area CA according to some implementations, as the second BCC is formed under the bit line D2, the reference bit line D3_ref and the reference bit line D_ref 1 may be connected to each other through the second BCC, thereby forming the target reference bit line TRBL. The first reference current IREF1 may generate the first reference signal by passing through the resistive element RM, without passing through the NRC, by using the second BCC. In the wiring structure of the OTP cell area OCA, as the ORCs are arranged under the reference bit line D3_ref, the second reference current IREF2 may generate the second reference signal by passing through the switch transistor ST (bypassing the resistive element RM) and passing through the OTP reference cell. In other words, the memory device may generate the reference signal by different methods depending on whether a read operation is the read operation of the NMC or the read operation of the OMC.

The memory device according to some implementations may form the target reference bit line TRBL through the second BCC of the connection area, and include the NMC and the OMC in an IP block (or one memory chip) by sharing the target reference bit line TRBL between the NRC and the ORC. Furthermore, the memory device may increase the read margin of each memory cell by varying the generation method of the reference signal (e.g., a generation method based on a fixed resistance value / a hybrid generation method based on a connection/combination of a plurality of reference cells) depending on the type of the memory cell, through the second BCC connected to the target reference bit line TRBL.

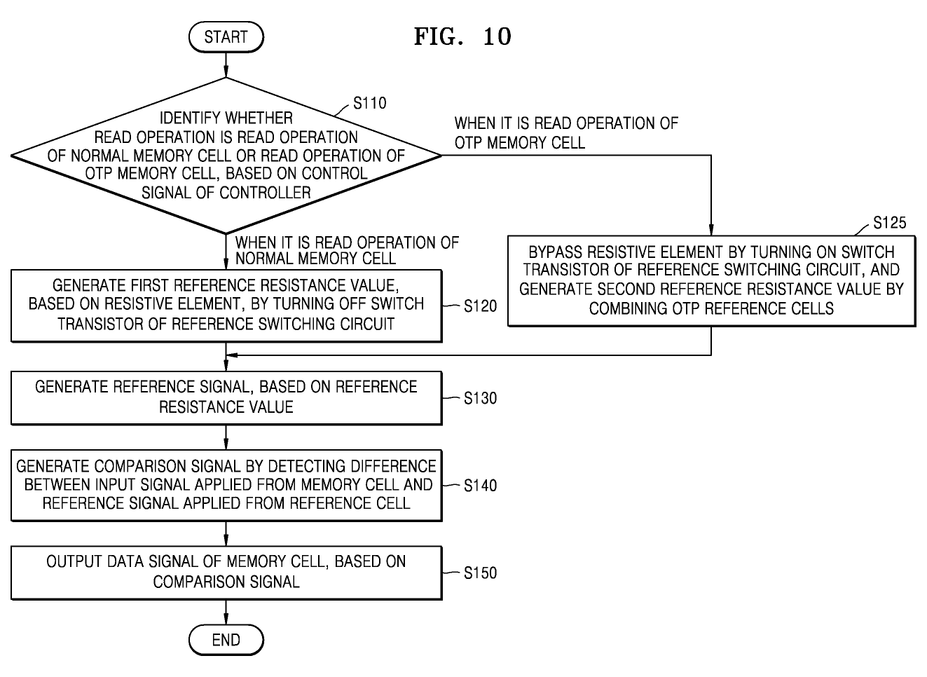

FIG. 10 is a flowchart of a method of operating a memory device, according to some implementations.

Referring to FIG. 10, when a normal reference cell and an OTP reference cell share a reference bit line, a method of operating the memory device 10 to read data stored in the memory cell may include operation S110 to operation S150. In FIG. 10, a target reference bit line may represent the reference bit line shared by the normal reference cell and the OTP reference cell. In the following description, FIGS. 1 and 9 are referred to together. Content overlapping with the above-described content is omitted.

In operation S110, the memory device 10 may determine whether a read operation is the read operation of the normal memory cell or the read operation of the OTP memory cell, based on the control signal of the controller 170. The memory device 10 may perform operation S120 when it is the read operation of the normal memory cell, and operation S125 when it is the read operation of the OTP memory cell.

In operation S120, the memory device 10 may generate a first reference resistance value based on the resistive element by turning off the switch transistor of a reference switching circuit.

In operation S125, the memory device 10 may bypass the resistive element by turning on the switch transistor of the reference switching circuit, and generate a second reference resistance value by connecting/combining resistances of at least two OTP reference cells (e.g., the variable resistance elements MTJs).

In operation S130, the memory device 10 may generate a reference signal based on the reference resistance value. In operation S140, the memory device 10 may generate a comparison signal by detecting a difference between an input signal applied from the memory cell and a reference signal applied from the reference cell. In operation S150, the memory device 10 may output a data signal of the memory cell based on the comparison signal.

When a result of the determination that the read operation is the read operation of a normal memory cell, the memory device 10 may transmit a first reference signal of the normal reference cell corresponding to the first reference resistance value to a sense amplifier through a target reference bit line, and generate a first comparison signal by detecting a difference between a first input signal applied from the normal memory cell and the first reference signal applied from the normal reference cell. The memory device 10 may output a data signal of the normal memory cell based on the first comparison signal.

When a result of the determination that the read operation is the read operation of the OTP memory cell, the memory device 10 may transmit a second reference signal of the OTP reference cell corresponding to the second reference resistance value to the sense amplifier through the target reference bit line, and generate a second comparison signal by detecting a difference between a second input signal applied from the OTP memory cell and a second reference signal applied from the OTP reference cell. The memory device 10 may output a data signal of the OTP memory cell based on the second comparison signal.

In some implementations, the OTP reference cell of the memory device 10 may be connected to the target reference bit line, and the normal reference cell may be connected to the target reference bit line through a plurality of cell vias. The cell vias may be formed under the target reference bit line in the normal reference area.

In some implementations, the normal reference cell of the memory device 10 may be connected to the first reference bit line arranged under the normal reference cell, and the OTP reference cell may be connected to the second reference bit line arranged above the OTP reference cell. The first reference bit line and the second reference bit line may be connected to each other through at least one cell via formed in the connection area so as to form the target reference bit line. The connection area may represent the area between the normal reference cell and the OTP reference cell (i.e., the area between the normal reference area NRA and the OTP reference area ORA), in FIG. 7.

In some implementations, the normal reference cell of the memory device 10 may be connected to the first reference bit line arranged under the normal reference cell, and the OTP reference cell may be connected to the second reference bit line arranged above the OTP reference cell. The first reference bit line and the second reference bit line may be connected to each other through the first BCCs connected in parallel in the connection area so as to form the, target reference bit line. The connection area may represent the area between the normal reference cell and the OTP reference cell (i.e., the area between the normal reference area NRA and the OTP reference area ORA), in FIG. 8. The method of operating the memory device 10 according to the disclosure may further include, to prevent I/O offset, before operation S120, an operation of presetting all of the first BCCs to a parallel state or an anti-parallel state.

In some implementations, the normal reference cell of the memory device 10 may be connected to the first reference bit line arranged under the normal reference cell, and the OTP reference cell may be connected to the second reference bit line arranged above the OTP reference cell. The first reference bit line and the second reference bit line may be connected to each other through the second bit line connection cell in the connection area so as to form the, target reference bit line. The connection area may represent the area between the normal reference cell and the OTP reference cell (i.e., the area between the normal reference area NRA and the OTP reference area ORA), in FIG. 9. The method of operating the memory device 10 according to the disclosure may further include, to prevent word line offset before operation S120, an operation of presetting the second bit line connection cell to a breakdown state by applying a predetermined amount of high bias to the second bit line connection cell.

The memory device 10 according to some implementations, in which the normal reference cell and the OTP reference cell are configured to share the reference bit line, has the technical effects of preventing core area waste and deterioration of offset properties of word lines due to the addition of separate reference bit lines for OTP reference cells, and improving the read margin of the memory device 10.

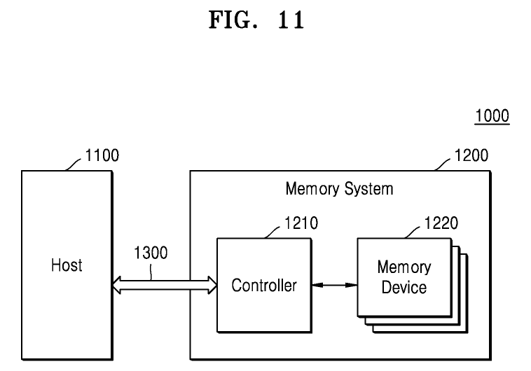

FIG. 11 is a block diagram of a memory system 1200 including a memory device according to some implementations.

Referring to FIG. 11, the memory system 1200 may communicate with a host 1100 and include a memory controller 1210 and a memory device 1220. The memory device 1220 may be applied to the memory device 10 described with reference to FIGS. 1-10.

An interface 1300 for communicating between the memory system 1200 and the host 1100 may use electrical signals and/or optical signals in a wired or wireless manner, and may be implemented by, as a non-limiting example, a serial advanced technology attachment (SATA) interface, a SATA express (SATAe) interface, a serial attached small computer system interface (SAS), a peripheral component interconnect express (PCIe) interface, a non-volatile memory express (NVMe) interface, an advanced host controller interface (AHCI), or a combination thereof.

In some implementations, as the memory system 1200 is removably combined with the host 1100, the memory system 1200 may communicate with the host 1100. As a resistivity memory, the memory device 1220 may be a non-volatile memory, and the memory system 1200 may be referred to as a storage system. For example, the memory system 1200 may be implemented by, as a non-limiting example, a solid-state drive or solid-state disk (SSD), an embedded SSD (eSSD), a multimedia card (MMC), or an embedded multimedia card (eMMC).

The memory controller 1210 may control the memory device 1220 in response to a request received from the host 1100 through the interface 1300. For example, the memory controller 1210 may write, in response to a write request, data received accompanied by the write request to the memory device 1220, and provide, in response to a read request, data stored in the memory device 1220 to the host 1100.

The memory system 1200 may include at least one memory device 1220. The memory device 1220 may be implemented as the memory device 10 described with reference to FIGS. 1-10.

In some implementations, the memory system 1200 includes the memory controller 1210; and the memory device 1220 including a cell array and a reference switching circuit, the cell array including a normal memory cell capable of multiple programming, an OTP memory cell capable of one-time programming, a normal reference cell, and an OTP reference cell, and the reference switching circuit connected to the cell array through a target reference bit line, wherein the normal reference cell and the OTP reference cell are configured to share the target reference bit line, and the memory device 1220 generates a first reference signal based on a resistive element of the reference switching circuit, by using the target reference bit line, when it is a read operation of the normal memory cell, and generates a second reference signal based on the switch transistor of reference switching circuit and a variable resistance element of the OTP reference cell, by using the target reference bit line, when it is a read operation of the OTP memory cell.

The memory system 1200 according to some implementations may include the NMC and the OMC in an IP block (or one memory chip) by forming the target reference bit line TRBL based on various methods described with reference to FIGS. 6-9, and sharing the target reference bit line TRBL between the NRC and the ORC.

Furthermore, the memory system 1200 according to some implementations may increase the read margin of each memory cell by varying the generation method of the reference signal (e.g., a generation method based on a fixed resistance value / a hybrid generation method based on a connection/combination of a plurality of reference cells) depending on the type of the memory cell, based on the reference switching circuit RSC.

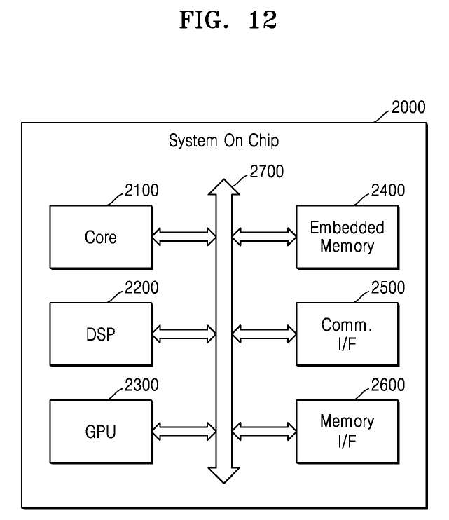

FIG. 12 is a block diagram illustrating a system-on-chip (SoC) 2000 including a memory device according to some implementations.

Referring to FIG. 12, the system-on-chip 2000 may include a core 2100, a digital signal processor (DSP) 2200, a graphics processing unit (GPU) 2300, an internal memory 2400, a communication interface 2500, and a memory interface 2600. The components of the system-on-chip 2000 may communicate with each other through a bus 2700.

The system-on-chip 2000 may refer to an integrated circuit that integrates components of a computing system or other electronic system. For example, an application processor (AP), as one example of the system-on-chip 2000, may include a processor and components for other functions.

The core 2100 may process instructions, and control operations of components included in the system-on-chip 2000. For example, the core 2100 may drive an operating system by processing a series of instructions, and execute applications on the operating system. The DSP 2200 may generate useful data by processing digital signals, for example, digital signals provided from the communication interface 2500. The GPU 2300 may generate data for an image to be output through a display device, or encode the image data, from the image data provided from the internal memory 2400 or the memory interface 2600. The communication interface 2500 may provide an interface for a communication network or one-to-one communication. The memory interface 2600 may provide an interface for external memory of the system-on-chip 2000, for example, dynamic random access memory (DRAM) or flash memory.

The internal memory 2400 may store data needed for the operations of the core 2100, the DSP 2200, and the GPU 2300. The internal memory 2400 may include the memory device 10 described with reference to FIGS. 1-10.

While the disclosure has been particularly shown and described with reference to implementations thereof, it will be understood that various changes in form and details may be made therein without departing from the spirit and scope of the following claims.

What is claimed is:

1. A memory device comprising:
a controller configured to generate, based on a type of memory cell, a control signal to perform a read operation of the memory device;
a cell array comprising:
a normal memory area including a normal memory cell for multiple programming,
a one-time programmable (OTP) memory area including an OTP memory cell capable of one-time programming,
a normal reference area including a normal reference cell corresponding to the normal memory cell, and
an OTP reference area including an OTP reference cell corresponding to the OTP memory cell; and
a sense amplifier configured to generate a comparison signal based on a difference between an input signal from the memory cell and a reference signal from the reference cell,
wherein the normal reference cell and the OTP reference cell are configured to share a target reference bit line.

2. The memory device of claim 1, wherein the target reference bit line is connected to the sense amplifier through a reference switching circuit, the reference switching circuit comprising a resistive element and a switch transistor.

3. The memory device of claim 2, wherein the reference switching circuit is configured to, based on the normal memory cell being read, turn the switch transistor off according to the control signal and configured to, based on the resistive element, generate a first reference resistance value, and
wherein the reference switching circuit is configured to, based on the OTP memory cell being read, (i) turn the switch transistor on according to the control signal and bypass the resistive element, and (ii) combine a plurality of OTP reference cells to generate a second reference resistance value.

4. The memory device of claim 1, wherein the OTP reference cell is connected to the target reference bit line,
the normal reference cell is connected to the target reference bit line through a plurality of cell vias in the normal reference area, and
the plurality of cell vias are under the target reference bit line in the normal reference area.

5. The memory device of claim 1, wherein the normal reference cell is connected to a first reference bit line arranged under the normal reference cell,
the OTP reference cell is connected to a second reference bit line arranged above the OTP reference cell,
the first reference bit line and the second reference bit line are connected to each other through at least one cell via formed in a connection area and form the target reference bit line, and
the connection area is in the cell array between the normal reference area and the OTP reference area.

6. The memory device of claim 1, wherein the normal reference cell is connected to a first reference bit line arranged under the normal reference cell,
the OTP reference cell connected to a second reference bit line arranged above the OTP reference cell,
the first reference bit line and the second reference bit line are connected to each other through a plurality of first bit line connection cells connected in parallel in a connection area and form the target reference bit line, and
the connection area is in the cell array between the normal reference area and the OTP reference area.

7. The memory device of claim 6, wherein the plurality of first bit line connection cells are preset to a parallel state or an anti-parallel state before the memory cell is read.

8. The memory device of claim 1, wherein the normal reference cell is connected to a first reference bit line arranged under the normal reference cell,
the OTP reference cell is connected to a second reference bit line arranged above the OTP reference cell,
the first reference bit line and the second reference bit line are connected to each other through a second bit line connection cell in a connection area and form the target reference bit line, and
the connection area is in the cell array between the normal reference area and the OTP reference area.

9. The memory device of claim 8, wherein the second bit line connection cell is preset to a breakdown state based on a high bias being applied to the second bit line connection cell.

10. The memory device of claim 1, wherein the normal memory cell and the OTP memory cell each comprise a variable resistance element and at least one cell transistor.

11. A method of operating a memory device, the memory device comprising a normal memory cell for multiple programming, a one-time programmable (OTP) memory cell for one-time programming, a normal reference cell, an OTP reference cell, and a reference switching circuit, the method comprising:
determining, based on a control signal received from a memory controller, that a read operation is a read operation of the normal memory cell or a read operation of the OTP memory cell; and
based on determining that the read operation is the read operation of the normal memory cell, generating a first reference resistance value based on a resistive element of the reference switching circuit by turning off a switch transistor of the reference switching circuit; and
based on determining that the read operation is the read operation of the OTP memory cell, generating a second reference resistance value (i) by turning on the switch transistor of the reference switching circuit and bypassing the resistive element of the reference switching circuit, and (ii) by combining a plurality of OTP reference cells,
wherein the normal reference cell and the OTP reference cell are configured to share a target reference bit line and are connected to the reference switching circuit through the target reference bit line.

12. The method of claim 11, comprising, based on determining that the read operation is the read operation of the normal memory cell:
transmitting a first reference signal of the normal reference cell corresponding to the first reference resistance value to a sense amplifier through a target reference bit line;
generating a first comparison signal by detecting a difference between a first input signal applied from the normal memory cell and the first reference signal input from the normal reference cell; and
outputting, based on the first comparison signal, a data signal of the normal memory cell.

13. The method of claim 11, comprising, based on determining that the read operation is the read operation of the OTP memory cell:
transmitting a second reference signal of the OTP reference cell corresponding to the second reference resistance value to a sense amplifier through a target reference bit line;
generating a second comparison signal by detecting a difference between a second input signal applied from the OTP memory cell and the second reference signal applied from the OTP reference cell; and
outputting, based on the second comparison signal, a data signal of the OTP memory cell.

14. The method of claim 11, wherein the target reference bit line is connected to a sense amplifier through the reference switching circuit.

15. The method of claim 11, wherein the OTP reference cell is connected to the target reference bit line,
the normal reference cell is connected to the target reference bit line through a plurality of cell vias, and
the plurality of cell vias are under the target reference bit line in a normal reference area including the normal reference cell.

16. The method of claim 11, wherein the normal reference cell is connected to a first reference bit line arranged under the normal reference cell,
the OTP reference cell is connected to a second reference bit line arranged above the OTP reference cell,
the first reference bit line and the second reference bit line are connected to each other through at least one cell via formed in a connection area and form the target reference bit line, and
the connection area is in a cell array between a normal reference area including the normal reference cell and an OTP reference area including the OTP reference cell.

17. The method of claim 11, wherein the normal reference cell is connected to a first reference bit line arranged under the normal reference cell,
the OTP reference cell is connected to a second reference bit line arranged above the OTP reference cell,
the first reference bit line and the second reference bit line are connected to each other through a plurality of first bit line connection cells connected in parallel in a connection area and form the target reference bit line, and
the connection area is between a normal reference area including the normal reference cell and an OTP reference area including the OTP reference cell.

18. The method of claim 11, wherein the normal reference cell is connected to a first reference bit line arranged under the normal reference cell,
the OTP reference cell is connected to a second reference bit line arranged above the OTP reference cell,
the first reference bit line and the second reference bit line are connected to each other through a second bit line connection cell in a connection area and form the target reference bit line, and
the connection area is in a cell array between a normal reference area including the normal reference cell and an OTP reference area including the OTP reference cell.

19. The method of claim 11, wherein the normal memory cell and the OTP memory cell each comprise a variable resistance element and at least one cell transistor.

20. A memory system comprising:
a memory controller; and
a memory device comprising a cell array and a reference switching circuit, the cell array including a normal memory cell capable of multiple programming, a one-time programmable (OTP) memory cell capable of one-time programming, a normal reference cell, and an OTP reference cell, and the reference switching circuit connected to the cell array through a target reference bit line,
wherein the normal reference cell and the OTP reference cell are configured to share the target reference bit line, and
wherein the memory device is configured to:
based on a read operation being a read operation of the normal memory cell, generate a first reference signal based on a resistive element of the reference switching circuit by using the target reference bit line; and
based on the read operation being a read operation of the OTP memory cell, generate a second reference signal based on a switch transistor of the reference switching circuit and a variable resistance element of the OTP reference cell by using the target reference bit line.
